(19) United States
(12) Patent Application Publication
(10) Pub. No.: US 2026/0036645 A1
(43) Pub. Date: Feb. 5, 2026

(54) LOAD TESTING SYSTEM

(71) Applicant: TATSUMI RYOKI CO., LTD, Tokyo (JP)

(72) Inventor: Toyoshi KONDO, Tokyo (JP)

(21) Appl. No.: 19/279,659

(22) Filed: Jul. 24, 2025

Related U.S. Application Data
(63) Continuation of application No. PCT/JP2024/000803, filed on Jan. 15, 2024.

(30) Foreign Application Priority Data
Feb. 2, 2023 (JP) 2023-014937
Feb. 20, 2023 (JP) 2023-024085
Feb. 28, 2023 (JP) 2023-029182
Jul. 12, 2023 (JP) 2023-114166

(51) Int. Cl. G01R 31/40

(52) U.S. Cl. CPC G01R 31/40

(57) ABSTRACT

A load testing system includes a plurality of sets of load testing devices each including a first load testing section including one or more resistance units and a first breaker device. Power supply from a test target power supply to at least one resistance unit among the one or more resistance units is performed at least via a breaker section separate from the load testing device, and the first breaker device. The breaker section performs on-off control on power supply to at least one load testing device among the plurality of sets of load testing devices. The first breaker device performs on-off control on power supply to at least a resistance unit connected to the first breaker device among the one or more resistance units.

### CROSS-REFERENCE TO RELATED APPLICATIONS

This application is a continuation application of International Patent Application No. PCT/JP2024/000803 filed on Jan. 15, 2024, which claims priorities from Japanese Patent Applications No. 2023-014937 filed on Feb. 2, 2023, 2023-024085 filed on Feb. 20, 2023, 2023-029182 filed on Feb. 28, 2023, and 2023-114166 filed on Jul. 12, 2023, the entire contents of which are incorporated by reference.

### TECHNICAL FIELD

The present invention relates to a load testing system and the like.

### BACKGROUND ART

Load testing devices have been proposed as in Patent Literature 1.

### CITATION LIST

### Patent Literature

Patent Literature 1: JP 2000-019231 A

### SUMMARY OF INVENTION

### Technical Problem

However, safety in conducting a load test on a test target power supply is not sufficient secured.

Therefore, the present invention aims to provide a load testing system capable of safely conducting a load test on a test target power supply.

### Solution to Problem

A load testing system according to the present invention includes a plurality of sets of load testing devices each including a first load testing section including one or more resistance units and a first breaker device.

Power supply from the test target power supply to at least one resistance unit among the one or more resistance units is performed at least via a breaker section separate from the load testing device, and the first breaker device.

The breaker section performs on-off control on power supply to at least one load testing device among the plurality of sets of load testing devices.

The first breaker device performs on-off control on power supply to at least a resistance unit connected to the first breaker device among the one or more resistance units.

Since the power supply from the test target power supply to resistor groups is performed via a plurality of breaking means, the possibility that the power supply to the resistor groups is erroneously performed can be lowered even in a case where there is a failure in one of the breaking means, and thus, a load test can be safely conducted on the test target power supply.

Preferably, the one or more resistance units include a first U-phase resistance unit, a second U-phase resistance unit, a third U-phase resistance unit, a first V-phase resistance unit, a second V-phase resistance unit, a third V-phase resistance unit, a first W-phase resistance unit, a second W-phase resistance unit, and a third W-phase resistance unit.

The load testing device includes: a first load testing section including the first U-phase resistance unit, the second U-phase resistance unit, the first V-phase resistance unit, the second V-phase resistance unit, the first W-phase resistance unit, the second W-phase resistance unit, and the first breaker device; and a second load testing section including the third U-phase resistance unit, the third V-phase resistance unit, and the third W-phase resistance unit.

Power supply from the test target power supply to the first U-phase resistance unit, the second U-phase resistance unit, the first V-phase resistance unit, the second V-phase resistance unit, the first W-phase resistance unit, and the second W-phase resistance unit is performed at least via the breaker section and the first breaker device.

Power supply from the test target power supply to the third U-phase resistance unit, the third V-phase resistance unit, and the third W-phase resistance unit is performed at least via the breaker section and the first breaker device or a second breaker device provided in the second load testing section.

By including large-capacity resistors in the resistor group of each resistance unit, it is possible to safely conduct a load test on the high-voltage test target power supply.

In particular, there is no need to step down the voltage of the power from the test target power supply with a transformer or the like.

Thus, unlike a load test involving step-down by a transformer or the like, it is possible to supply power to each load testing section using a thin power supply cable.

Also, unlike a mode involving step-down by a transformer or the like, it is possible to conduct a load test in a state similar to actual use.

Further, the first load testing section and the second load testing section can be used in separate load tests, or can be collectively used in one load test.

More preferably, resistors of a resistor group of each of the one or more resistance units extend in an x direction.

The first U-phase resistance unit, the second U-phase resistance unit, the third U-phase resistance unit, the first V-phase resistance unit, the second V-phase resistance unit, the third V-phase resistance unit, the first W-phase resistance unit, the second W-phase resistance unit, and the third W-phase resistance unit are arranged in a y direction perpendicular to the x direction.

Of a holding frame holding the resistor group of each of the one or more resistance units, a surface holding terminals of the resistors is covered with a detachable transparent cover.

Adhesion of dust or the like to the edge portions of the terminals of the resistors can be reduced.

Furthermore, even in a case where there is adhesion of dust or the like, the dust or the like can be easily recognized with the eye from the outside, and be easily removed.

Also preferably, resistors of a resistor group of each of the one or more resistance units extend in an x direction.

The first U-phase resistance unit, the second U-phase resistance unit, the third U-phase resistance unit, the first V-phase resistance unit, the second V-phase resistance unit, the third V-phase resistance unit, the first W-phase resistance unit, the second W-phase resistance unit, and the third W-phase resistance unit are arranged in a y direction perpendicular to the x direction.

At least the first U-phase resistance unit includes a cooling section that cools the resistor group of the first U-phase resistance unit.

The cooling section of the first U-phase resistance unit includes two cooling fans arranged in the x direction.
a guide wall including an inclined surface is provided in the cooling section of the first U-phase resistance unit.

The guide wall guides cooling air from one of the cooling fans toward a rotation axis of the one of the cooling fans, and guides cooling air from the other one of the cooling fans toward a rotation axis of the other one of the cooling fans.

The direction in which cooling air flows is controlled, and the cooling air is easily supplied to a wide range of the region in which a resistor group including long resistors is present.

Also preferably, the one or more resistance units include the first U-phase resistance unit, the second U-phase resistance unit, the third U-phase resistance unit, a fourth U-phase resistance unit, the first V-phase resistance unit, the second V-phase resistance unit, the third V-phase resistance unit, a fourth V-phase resistance unit, the first W-phase resistance unit, the second W-phase resistance unit, the third W-phase resistance unit, and a fourth W-phase resistance unit.

The first U-phase resistance unit and the second U-phase resistance unit are arranged in an x direction.

The first V-phase resistance unit and the second V-phase resistance unit are arranged in the x direction.

The first W-phase resistance unit and the second W-phase resistance unit are arranged in the x direction.

The third U-phase resistance unit and the fourth U-phase resistance unit are arranged in the x direction.

The third V-phase resistance unit and the fourth V-phase resistance unit are arranged in the x direction.

The third W-phase resistance unit and the fourth W-phase resistance unit are arranged in the x direction.

The first U-phase resistance unit, the first V-phase resistance unit, the first W-phase resistance unit, the third U-phase resistance unit, the third V-phase resistance unit, and the third W-phase resistance unit are arranged in a y direction perpendicular to the x direction.

The second U-phase resistance unit, the second V-phase resistance unit, the second W-phase resistance unit, the fourth U-phase resistance unit, the fourth V-phase resistance unit, and the fourth W-phase resistance unit are arranged in the y direction.

A region including the first U-phase resistance unit, the second U-phase resistance unit, the first V-phase resistance unit, the second V-phase resistance unit, the first W-phase resistance unit, and the second W-phase resistance unit is provided between a region including the first breaker device and a region including the third U-phase resistance unit, the fourth U-phase resistance unit, the third V-phase resistance unit, the fourth V-phase resistance unit, the third W-phase resistance unit, and the fourth W-phase resistance unit.

A distance in the y direction between the first U-phase resistance unit and the first V-phase resistance unit, and a distance in the y direction between the first W-phase resistance unit and the third U-phase resistance unit are longer than a distance in the y direction between the first V-phase resistance unit and the first W-phase resistance unit.

The load testing devices can be housed in a 40-feet container, while sufficient electrical separation is maintained.

Also, an operator can enter a region having a large interval in the y direction, such as between the first U-phase resistance unit and the first V-phase resistance unit, and perform operations such as maintenance.

Also preferably, the one or more resistance units include the first U-phase resistance unit, the second U-phase resistance unit, the third U-phase resistance unit, a fourth U-phase resistance unit, the first V-phase resistance unit, the second V-phase resistance unit, the third V-phase resistance unit, a fourth V-phase resistance unit, the first W-phase resistance unit, the second W-phase resistance unit, the third W-phase resistance unit, and a fourth W-phase resistance unit.

The first U-phase resistance unit and the second U-phase resistance unit are arranged in an x direction.

The first V-phase resistance unit and the second V-phase resistance unit are arranged in the x direction.

The first W-phase resistance unit and the second W-phase resistance unit are arranged in the x direction.

The third U-phase resistance unit and the fourth U-phase resistance unit are arranged in the x direction.

The third V-phase resistance unit and the fourth V-phase resistance unit are arranged in the x direction.

The third W-phase resistance unit and the fourth W-phase resistance unit are arranged in the x direction.

The first U-phase resistance unit, the first V-phase resistance unit, the first W-phase resistance unit, the third U-phase resistance unit, the third V-phase resistance unit, and the third W-phase resistance unit are arranged in a y direction perpendicular to the x direction.

The second U-phase resistance unit, the second V-phase resistance unit, the second W-phase resistance unit, the fourth U-phase resistance unit, the fourth V-phase resistance unit, and the fourth W-phase resistance unit are arranged in the y direction.

The resistors of a resistor group in each of the first U-phase resistance unit, the second U-phase resistance unit, the third U-phase resistance unit, the fourth U-phase resistance unit, the first V-phase resistance unit, the second V-phase resistance unit, the third V-phase resistance unit, the fourth V-phase resistance unit, the first W-phase resistance unit, the second W-phase resistance unit, the third W-phase resistance unit, and the fourth W-phase resistance unit extend in the y direction.

A distance between a holding frame holding the resistor group in the first U-phase resistance unit and a holding frame holding the resistor group in the first V-phase resistance unit, a distance between the holding frame of the first V-phase resistance unit and a holding frame holding the resistor group in the first W-phase resistance unit, a distance between a holding frame holding the resistor group in the third U-phase resistance unit and a holding frame holding the resistor group in the third V-phase resistance unit, and a distance between the holding frame of the third V-phase resistance unit and a holding frame holding the resistor group in the third W-phase resistance unit are 80% of a width in the y direction of the holding frame of the first U-phase resistance unit.

The distance between adjacent holding frames is about 80% of the length in the longitudinal direction of the resistor R substantially equal to the length of the holding frames.

Thus, while electrical separation is sufficiently maintained, the load testing device can be housed in a container having a predetermined size, and furthermore, resistors extending in the y direction can be easily taken out from between a holding frame and a holding frame.

More preferably, the region including the first breaker device is disposed between the region including the first U-phase resistance unit, the second U-phase resistance unit, the first V-phase resistance unit, the second V-phase resistance unit, the first W-phase resistance unit, and the second W-phase resistance unit, and the region including the third U-phase resistance unit, the fourth U-phase resistance unit, the third V-phase resistance unit, the fourth V-phase resistance unit, the third W-phase resistance unit, and the fourth W-phase resistance unit.

The region including the first breaker device is disposed at the center in the y direction, and, on both sides of the region, the region including the first U-phase resistance unit or the like and the region including the third U-phase resistance unit or the like are disposed, so that the weight balance in the longitudinal direction of one container can be enhanced.

Also preferably, each of the one or more resistance units includes a resistor group, a holding frame that holds the resistor group, and a cooling section that cools the resistor group.

The resistor group includes a plurality of resistors.

The plurality of resistors is arranged at least in a first direction perpendicular to the direction in which the cooling section and the holding frame are arranged.

In a region including a line along which a rotation axis of a cooling fan of the cooling section extends, and a center in the first direction of a region in which the plurality of resistors is arranged, the resistors are arranged at wider intervals than in other regions in which the plurality of resistors is arranged.

Compared with that in a mode in which the resistors are arranged at equal intervals in the first direction, the cooling air easily flows in the region including the rotation axis.

Also preferably, each of the one or more resistance units includes a holding frame that holds a resistor group of each of the one or more resistance units.

A projection that diffuses cooling air is formed on an inner wall of the holding frame.

The protrusion changes the direction in which the cooling air flows, and the cooling air easily diffuses in the holding frame.

Also preferably, each of the one or more resistance units includes a holding frame that holds a resistor group of each of the one or more resistance units, and a cooling section that cools the resistor group.

The cooling section includes a plurality of cooling fans.

The plurality of cooling fans is arranged in an inclined state with respect to a plane perpendicular to a direction in which the cooling section and the holding frame are arranged to make cooling airs collide with each other in a region including the resistor group.

As the cooling airs from the plurality of cooling fans collide with each other in the region including the resistor group, and the directions in which the cooling airs flow change, the cooling airs easily diffuse in the holding frame.

Also preferably, the load testing system further includes a controller that is connected to each load testing device among the plurality of sets of load testing devices in a wired manner, and transmits a control signal to each load testing device among the plurality of sets of load testing devices.

The single controller can collectively manage operation control of a plurality of load testing devices (a plurality of load testing sections). Also, because of the wired connection, it is possible to safely and reliably perform operation control of a plurality of load testing devices (a plurality of load testing sections) which positions away, unless there is physical breakage.

Also preferably, each of the one or more resistance units includes a cooling section that cools a resistor group of each of the one or more resistance units.

The cooling section includes a cooling fan that is driven by power from the test target power supply.

The first breaker device has a power storage section that stores the power from the test target power supply.

The power storage section drives the cooling fan when power supply from the test target power supply is cut off.

It is possible to drive each component of the load testing device, using the power from the test target power supply, without any auxiliary power supply provided separately from the test target power supply.

In particular, the cooling fan and the like can be stably driven even when power supply from the test target power supply is cut off.

Also preferably, the plurality of sets of load testing devices includes at least a first load testing device, a second load testing device, a third load testing device, a fourth load testing device, and a fifth load testing device.

The breaker section includes at least a first breaker section and a second breaker section.

Power supply from the test target power supply to the first load testing device, the second load testing device, and the third load testing device is performed at least via the first breaker section.

Power supply from the test target power supply to the fourth load testing device and the fifth load testing device is performed at least via the second breaker section.

A plurality of breaker sections is provided, and each of said breaker sections is connected to two or three load testing devices. Thus, it is possible to configure the load testing system of the present invention, using smaller-capacity breaker sections compared with a mode in which one breaker section is connected to a large number of load testing devices. Also, it is possible to reduce the number of load testing devices that will be affected in a case where a failure occurs in a breaker section.

Also preferably, each of the one or more resistance units includes a resistor group, a holding frame that holds the resistor group, a cooling section that cools the resistor group, and an insulator provided between the holding frame and the cooling section.

The insulator and the cooling section are attached to each other via a first attachment fitting.

The insulator and the holding frame are attached to each other via a second attachment fitting separate from the first attachment fitting.

It is possible to fix an insulator between a cooling section and a holding frame in a simple and reliable manner.

Also, it is possible to easily replace only the insulator with a new insulator, compared with a mode in which the insulator is attached directly to a holding frame or the like without any attachment fitting.

More preferably, each of the one or more resistance units includes a hood including a first insulating plate and a second insulating plate.

The first insulating plate is attached to the cooling section via a third attachment fitting that is separate from the first attachment fitting and the second attachment fitting.

The second insulating plate is attached to the cooling section via the first attachment fitting.

An edge portion of the hood is located on an inner side of the holding frame.

Cooling air from the cooling section can be supplied to the inside of the holding frame without leaking to the outside, while insulation properties are maintained.

The members (the first insulating plate and the second insulating plate) constituting the hood can be easily attached and detached via the members (the first attachment fitting and the third attachment fitting) for securing the insulator.

Also preferably, the cooling section includes a cooling fan of a pressurized fan type including a bell mouth.

Even in a mode in which a space for taking in air is small, it is easy to send cooling air to the resistor groups.

Also preferably, power supply from the test target power supply to at least one of the one or more resistance units is performed at least via the breaker section, the first breaker device, and a switching device of the one or more resistance units.

The switching device performs on-off control on power supply to each of the one or more resistance unit, or on-off control on power supply to each resistor group among a plurality of resistor groups provided in each of the one or more resistance units.

Since the power supply from the test target power supply to the resistor groups is performed via a plurality of breaking means (the breaker sections, the breaker devices, and the switching devices), the possibility that the power supply to the resistor groups is erroneously performed can be lowered even in a case where there is a failure in one of the breaking means.

Also preferably, the one or more resistance units are formed with one resistance unit.

A housing of each load testing device among the plurality of sets of load testing devices holds a resistor group in the one resistance unit.

### Advantageous Effects of Invention

As described above, according to the present invention, a load testing system capable of safely conducting a load test on a test target power supply can be provided.

### BRIEF DESCRIPTION OF DRAWINGS

FIG. 1 is a configuration diagram of a load testing system according to a first embodiment.

FIG. 2 is a configuration diagram of a first load testing device and a first breaker section in the first embodiment.

FIG. 3 is a diagram illustrating an internal configuration of a first U-phase resistance unit, as viewed from the y direction.

FIG. 4 is a diagram illustrating an internal configuration of the first U-phase resistance unit, as viewed from the x direction.

FIG. 5 is a diagram illustrating an internal configuration of the first U-phase resistance unit including a plurality of eleventh U-phase cooling fans arranged obliquely.

FIG. 6 is a diagram illustrating internal structures of an eleventh housing and a twelfth housing as viewed from the x direction.

FIG. 7 is a diagram illustrating an internal structure of the twelfth housing as viewed from the y direction.

FIG. 8 is a configuration diagram of a load testing system according to a second embodiment.

FIG. 9 is a configuration diagram of a first load testing device and a first breaker section in the second embodiment.

FIG. 10 is a configuration diagram of a load testing system according to a third embodiment.

FIG. 11 is a configuration diagram of a first load testing device and a first breaker section in the third embodiment.

FIG. 12 is a diagram illustrating internal structures of an eleventh housing, a twelfth housing, and a twenty-second housing in the third embodiment, as viewed from the x direction.

FIG. 13 is a configuration diagram of a first load testing device and a first breaker section in a fourth embodiment.

FIG. 14 is a diagram illustrating internal structures of an eleventh housing, a twelfth housing, and a twenty-second housing in the fourth embodiment, as viewed from the x direction.

FIG. 15 is a diagram illustrating an internal structure of the twelfth housing in the fourth embodiment, as viewed from the y direction.

FIG. 16 is a configuration diagram of a first load testing section and a first breaker section in a fifth embodiment.

FIG. 17 is a diagram illustrating internal structures of an eleventh housing, a twelfth housing, and a twenty-second housing in the fifth embodiment, as viewed from the x direction.

FIG. 18 is a configuration diagram of a load testing system according to a sixth embodiment.

### DESCRIPTION OF EMBODIMENTS

In the following, a first embodiment is described with reference to the drawings.

Note that embodiments are not limited to the following embodiments. Also, the contents described in one embodiment are applied to other embodiments in principle. Further, each embodiment and each modification can be combined as appropriate.

### (Load Testing System 1)

A load testing system 1 according to the first embodiment includes load testing devices (first to twelfth load testing devices A1 to A12), a controller C1, and breaker sections (first to fourth breaker sections D1 to D4).

As for directions, a vertical direction in which a first U-phase resistance unit U1 and a second U-phase resistance unit U2 are arranged is defined as the x direction (the short-side direction of a container), a horizontal direction in which the first U-phase resistance unit U1, a first V-phase resistance unit V1, and a first W-phase resistance unit W1 are arranged is defined as the y direction (the longitudinal direction of the container), and an upward/downward direction perpendicular to the x direction and the y direction is defined as the z direction (the height direction of the container).

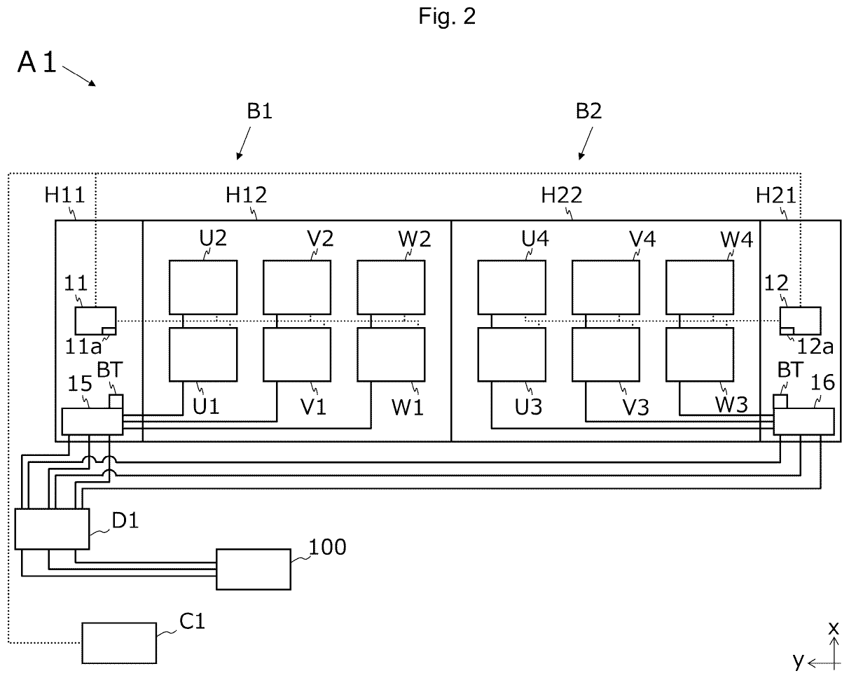

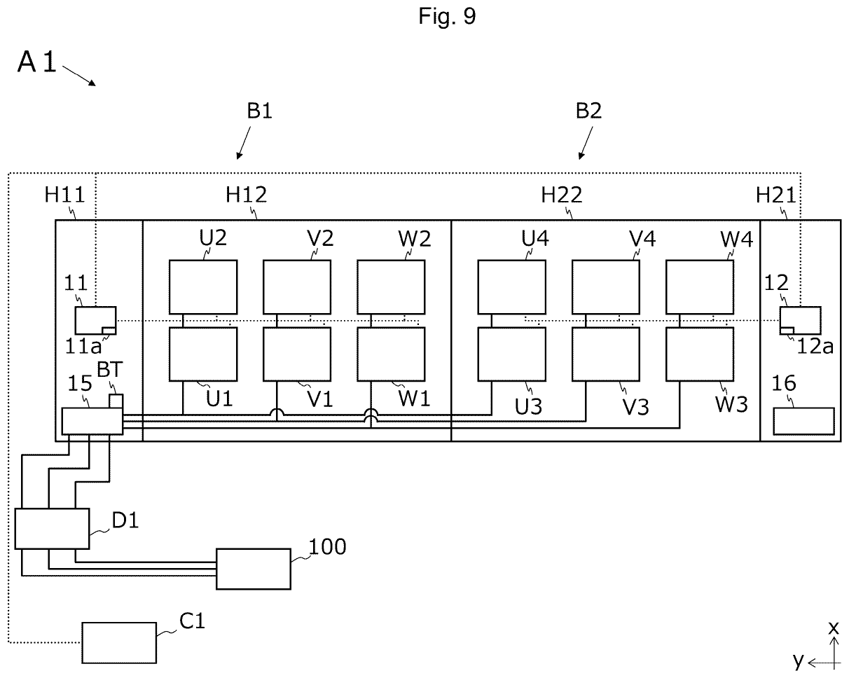

Note that, in FIG. 2 and FIGS. 9, 11, 13, and 16 to be described later, power supply cables and control signal cables to load testing devices (such as the second load testing device A2) other than the first load testing device A1 are not shown.

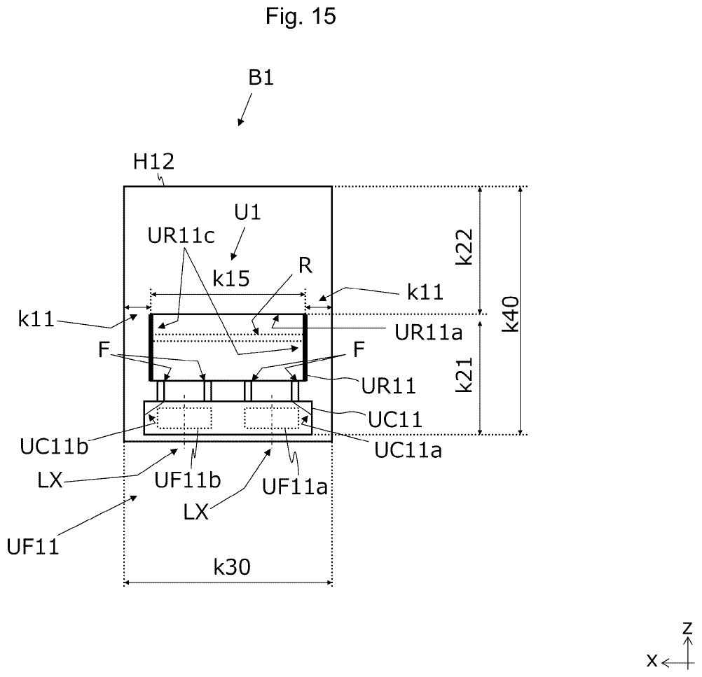

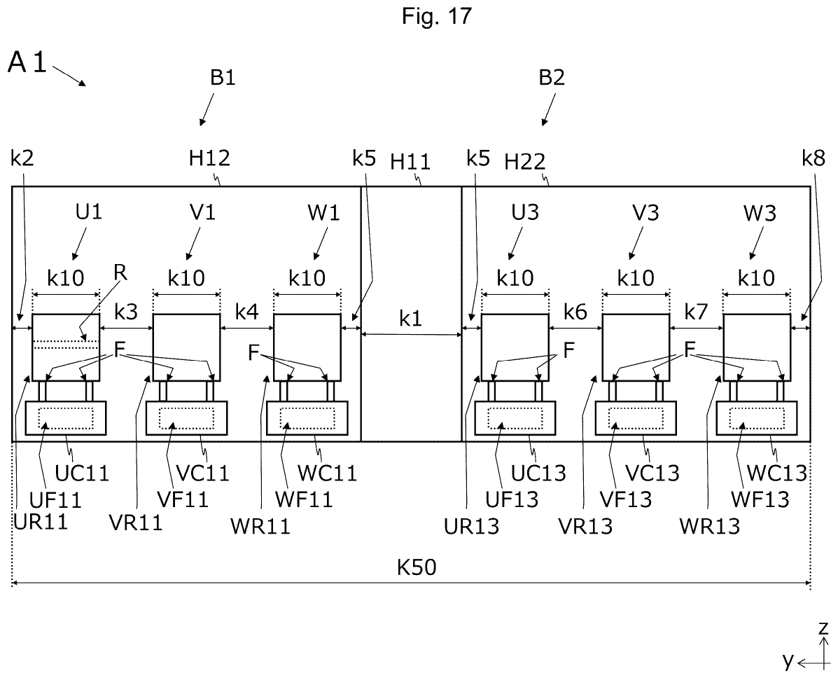

Further, in FIGS. 15 and 17 to be described later, only one resistor R provided in the first U-phase resistance unit U1 is shown with dotted lines.

### (First to Twelfth Load Testing Devices A1 to A12)

The first load testing device A1 includes a first load testing section B1 and a second load testing section B2.

The second load testing device A2 includes a third load testing section B3 and a fourth load testing section B4.

The third load testing device A3 includes a fifth load testing section B5 and a sixth load testing section B6.

The fourth load testing device A4 includes a seventh load testing section B7 and an eighth load testing section B8.

The fifth load testing device A5 includes a ninth load testing section B9 and a tenth load testing section B10.

The sixth load testing device A6 includes an eleventh load testing section B11 and a twelfth load testing section B12.

The seventh load testing device A7 includes a thirteenth load testing section B13 and a fourteenth load testing section B14.

The eighth load testing device A8 includes a fifteenth load testing section B15 and a sixteenth load testing section B16.

The ninth load testing device A9 includes a seventeenth load testing section B17 and an eighteenth load testing section B18.

The tenth load testing device A10 includes a nineteenth load testing section B19 and a twentieth load testing section B20.

The eleventh load testing device A11 includes a twenty-first load testing section B21 and a twenty-second load testing section B22.

The twelfth load testing device A12 includes a twenty-third load testing section B23 and a twenty-fourth load testing section B24.

### (Controller C1)

The controller C1 is configured separately from the load testing devices (the first to twelfth load testing devices A1 to A12).

The controller C1 has an operating portion to be used for selecting a load testing device to which power is to be supplied from a test target power supply 100.

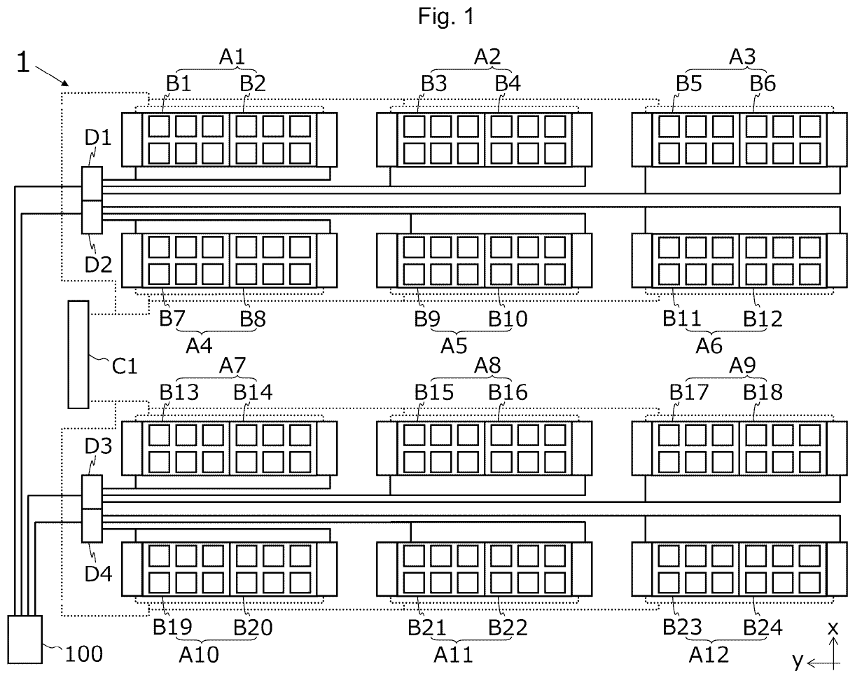

The controller C1 is connected to controllers (a first control device 11 and a second control device 12) of each load testing section in a wired manner through a control signal cable (see dotted lines in FIGS. 1 and 2), and transmits a control signal to a controller of each load testing section.

(Effects of Providing Controller C1 Separately from Load Testing Devices)

The single controller C1 can collectively manage operation control of a plurality of load testing devices (a plurality of load testing sections). Also, because of the wired connection, it is possible to safely and reliably perform operation control of a plurality of load testing devices (a plurality of load testing sections) which positions away, unless there is physical breakage.

Here, instead of/in addition to the operating portion of the controller C1, an operating portion may be provided for each load testing device or for each load testing section.

### (First Breaker Section D1)

The first breaker section D1 includes a vacuum circuit breaker (VCB), is connected to the test target power supply 100 on the input side, and is connected to breaker devices (a first breaker device 15 and a second breaker device 16) of the first to third load testing devices A1 to A3 on the output side.

The first breaker section D1 performs on-off control on the power supply to the first to third load testing devices A1 to A3.

Power supplied from the test target power supply 100 is supplied to a resistor group of the first load testing section B1 via the first breaker section D1 and the first breaker device 15 of the first load testing device A1.

Power supplied from the test target power supply 100 is supplied to the resistor group of the second load testing section B2 via the first breaker section D1 and the second breaker device 16 of the first load testing device A1.

Power supplied from the test target power supply 100 is supplied to the resistor group of the third load testing section B3 via the first breaker section D1 and the first breaker device (not shown) of the second load testing device A2.

Power supplied from the test target power supply 100 is supplied to the resistor group of the fourth load testing section B4 via the first breaker section D1 and the second breaker device (not shown) of the second load testing device A2.

Power supplied from the test target power supply 100 is supplied to the resistor group of the fifth load testing section B5 via the first breaker section D1 and the first breaker device (not shown) of the third load testing device A3.

Power supplied from the test target power supply 100 is supplied to the resistor group of the sixth load testing section B6 via the first breaker section D1 and the second breaker device (not shown) of the third load testing device A3.

### (Second Breaker Section D2)

The second breaker section D2 includes a vacuum circuit breaker, is connected to the test target power supply 100 on the input side, and is connected to the breaker devices of the fourth to sixth load testing devices A4 to A6 on the output side.

The second breaker section D2 performs on-off control on the power supply to the fourth to sixth load testing devices A4 to A6.

Power supplied from the test target power supply 100 is supplied to the resistor group of the seventh load testing section B7 via the second breaker section D2 and the first breaker device (not shown) of the fourth load testing device A4.

Power supplied from the test target power supply 100 is supplied to the resistor group of the eighth load testing section B8 via the second breaker section D2 and the second breaker device (not shown) of the fourth load testing device A4.

Power supplied from the test target power supply 100 is supplied to the resistor group of the ninth load testing section B9 via the second breaker section D2 and the first breaker device (not shown) of the fifth load testing device A5.

Power supplied from the test target power supply 100 is supplied to the resistor group of the tenth load testing section B10 via the second breaker section D2 and the second breaker device (not shown) of the fifth load testing device A5.

Power supplied from the test target power supply 100 is supplied to the resistor group of the eleventh load testing section B11 via the second breaker section D2 and the first breaker device (not shown) of the sixth load testing device A6.

Power supplied from the test target power supply 100 is supplied to the resistor group of the twelfth load testing section B12 via the second breaker section D2 and the second breaker device (not shown) of the sixth load testing device A6.

### (Third Breaker Section D3)

The third breaker section D3 includes a vacuum circuit breaker, is connected to the test target power supply 100 on the input side, and is connected to the breaker devices of the seventh to ninth load testing devices A7 to A9 on the output side.

The third breaker section D3 performs on-off control on the power supply to the seventh to ninth load testing devices A7 to A9.

Power supplied from the test target power supply 100 is supplied to the resistor group of the thirteenth load testing section B13 via the third breaker section D3 and the first breaker device (not shown) of the seventh load testing device A7.

Power supplied from the test target power supply 100 is supplied to the resistor group of the fourteenth load testing section B14 via the third breaker section D3 and the second breaker device (not shown) of the seventh load testing device A7.

Power supplied from the test target power supply 100 is supplied to the resistor group of the fifteenth load testing section B15 via the third breaker section D3 and the first breaker device (not shown) of the eighth load testing device A8.

Power supplied from the test target power supply 100 is supplied to the resistor group of the sixteenth load testing section B16 via the third breaker section D3 and the second breaker device (not shown) of the eighth load testing device A8.

Power supplied from the test target power supply 100 is supplied to the resistor group of the seventeenth load testing section B17 via the third breaker section D3 and the first breaker device (not shown) of the ninth load testing device A9.

Power supplied from the test target power supply 100 is supplied to the resistor group of the eighteenth load testing section B18 via the third breaker section D3 and the second breaker device (not shown) of the ninth load testing device A9.

### (Fourth Breaker Section D4)

The fourth breaker section D4 includes a vacuum circuit breaker, is connected to the test target power supply 100 on the input side, and is connected to the breaker devices of the tenth to twelfth load testing devices A10 to A12 on the output side.

The fourth breaker section D4 performs on-off control on the power supply to the tenth to twelfth load testing devices A10 to A12.

Power supplied from the test target power supply 100 is supplied to the resistor group of the nineteenth load testing section B19 via the fourth breaker section D4 and the first breaker device (not shown) of the tenth load testing device A10.

Power supplied from the test target power supply 100 is supplied to the resistor group of the twentieth load testing section B20 via the fourth breaker section D4 and the second breaker device (not shown) of the tenth load testing device A10.

Power supplied from the test target power supply 100 is supplied to the resistor group of the twenty-first load testing section B21 via the fourth breaker section D4 and the first breaker device (not shown) of the eleventh load testing device A11.

Power supplied from the test target power supply 100 is supplied to the resistor group of the twenty-second load testing section B22 via the fourth breaker section D4 and the second breaker device (not shown) of the eleventh load testing device A11.

Power supplied from the test target power supply 100 is supplied to the resistor group of the twenty-third load testing section B23 via the fourth breaker section D4 and the first breaker device (not shown) of the twelfth load testing device A12.

Power supplied from the test target power supply 100 is supplied to the resistor group of the twenty-fourth load testing section B24 via the fourth breaker section D4 and the second breaker device (not shown) of the twelfth load testing device A12.

### (Effects of Providing Plurality of Breaking Means)

Since the power supply from the test target power supply 100 to the resistor groups is performed via a plurality of breaking means (the breaker sections, the breaker devices, and the switching devices described later), the possibility that the power supply to the resistor groups is erroneously performed can be lowered even in a case where there is a failure in one of the breaking means, and thus, a load test can be safely conducted on the test target power supply 100.

Furthermore, a plurality of sets of existing load testing devices including breaker devices (such as the first breaker device 15) and the switching devices is provided, and breaker sections (such as the first breaker section D1) are further provided, so that the load testing system 1 of the present invention can be easily formed.

### (Effects of Providing Plurality of Breaker Sections)

A plurality of breaker sections (the first to fourth breaker sections D1 to D4) is provided, and each of said breaker sections is connected to two or three load testing devices. Thus, it is possible to configure the load testing system of the present invention, using smaller-capacity breaker sections compared with a mode in which one breaker section is connected to a large number of load testing devices. Also, it is possible to reduce the number of load testing devices that will be affected in a case where a failure occurs in a breaker section.

### (First Load Testing Section B1)

The first load testing section B1 includes six resistance units (the first U-phase resistance unit U1, the second U-phase resistance unit U2, the first V-phase resistance unit V1, a second V-phase resistance unit V2, the first W-phase resistance unit W1, and a second W-phase resistance unit W2), a controller (the first control device 11), and a breaker device (the first breaker device 15).

The first U-phase resistance unit U1 and the second U-phase resistance unit U2 each include a plurality of resistor groups and a cooling section that supplies cooling air to said plurality of resistor groups.

The resistor group of the first U-phase resistance unit U1 and the resistor group of the second U-phase resistance unit U2 are connected in series. However, the resistor group of the first U-phase resistance unit U1 and the resistor group of the second U-phase resistance unit U2 may be connected in parallel.

Power from an R-phase terminal of the test target power supply 100 is supplied to the resistor groups of the first U-phase resistance unit U1 and the second U-phase resistance unit U2 via the first breaker section D1 and the first breaker device 15.

Power from an auxiliary power supply provided separately from the test target power supply 100 is supplied to the cooling sections of the first U-phase resistance unit U1 and the second U-phase resistance unit U2.

Here, power from the test target power supply 100 may be supplied to the cooling sections of the first U-phase resistance unit U1 and the second U-phase resistance unit U2.

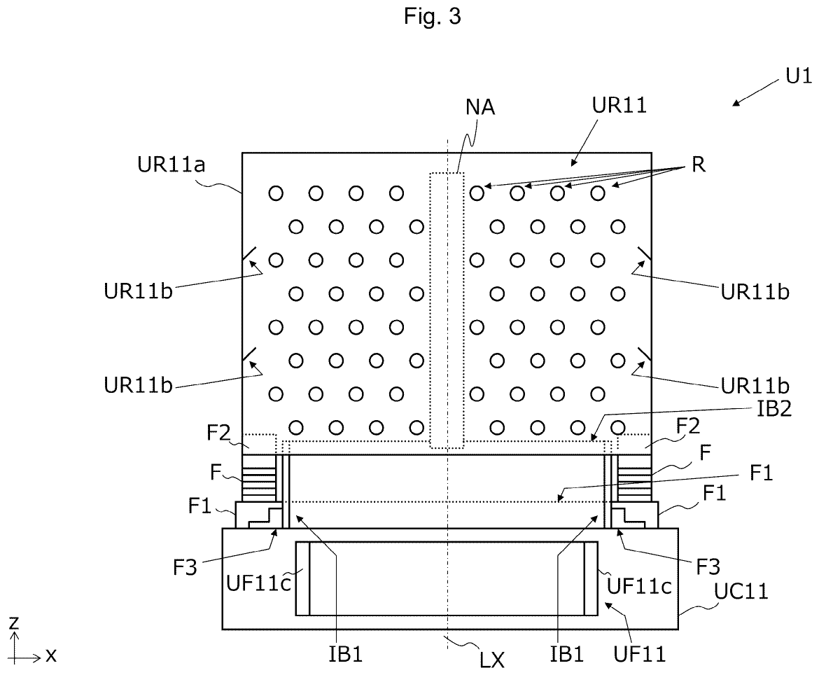

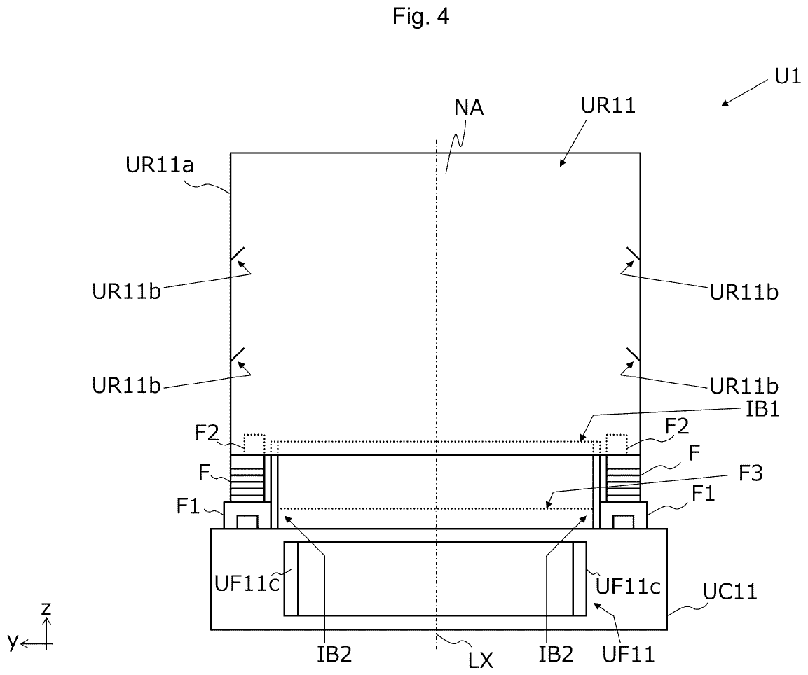

Next, the configurations of the resistor group and the cooling section of the first U-phase resistance unit U1 are described (see FIGS. 3 and 4).

In the following description, it is assumed that the resistor group of the first U-phase resistance unit U1 is an eleventh U-phase resistor group UR11, the cooling section of the first U-phase resistance unit U1 is an eleventh U-phase cooling section UC11, and a cooling fan of the eleventh U-phase cooling section UC11 is an eleventh U-phase cooling fan UF11.

In the following description, it is also assumed that the resistor group of the second U-phase resistance unit U2 is a twelfth U-phase resistor group UR12, the cooling section of the second U-phase resistance unit U2 is a twelfth U-phase cooling section UC12, and the cooling fan of the twelfth U-phase cooling section UC12 is a twelfth U-phase cooling fan UF12.

In the following description, it is also assumed that the resistor group of the first V-phase resistance unit V1 is an eleventh V-phase resistor group VR11, the cooling section of the first V-phase resistance unit V1 is an eleventh V-phase cooling section VC11, and the cooling fan of the eleventh V-phase cooling section VC11 is an eleventh V-phase cooling fan VF11.

In the following description, it is also assumed that the resistor group of the first W-phase resistance unit W1 is an eleventh W-phase resistor group WR11, the cooling section of the first W-phase resistance unit W1 is an eleventh W-phase cooling section WC11, and the cooling fan of the eleventh W-phase cooling section WC11 is an eleventh W-phase cooling fan WF11.

Note that the configurations of the twelfth U-phase resistor group UR12 of the second U-phase resistance unit U2, the eleventh V-phase resistor group VR11 of the first V-phase resistance unit V1, the resistor group of the second V-phase resistance unit V2, the eleventh W-phase resistor group WR11 of the first W-phase resistance unit W1, and the resistor group of the second W-phase resistance unit W2 are similar to the configuration of the eleventh U-phase resistor group UR11 of the first U-phase resistance unit U1.

Also, the configurations of the twelfth U-phase cooling section UC12 of the second U-phase resistance unit U2, the eleventh V-phase cooling section VC11 of the first V-phase resistance unit V1, the cooling section of the second V-phase resistance unit V2, the eleventh W-phase cooling section WC11 of the first W-phase resistance unit W1, and the cooling section of the second W-phase resistance unit W2 are similar to the configuration of the eleventh U-phase cooling section UC11 of the first U-phase resistance unit U1.

Also, the configurations of the twelfth U-phase cooling fan UF12 of the second U-phase resistance unit U2, the eleventh V-phase cooling fan VF11 of the first V-phase resistance unit V1, the cooling fan of the second V-phase resistance unit V2, the eleventh W-phase cooling fan WF11 of the first W-phase resistance unit W1, and the cooling fan of the second W-phase resistance unit W2 are similar to the configuration of the eleventh U-phase cooling fan UF11 of the first U-phase resistance unit U1.

### (Configuration of Eleventh U-Phase Cooling Section UC11)

The eleventh U-phase cooling section UC11 is disposed below the eleventh U-phase resistor group UR11.

The eleventh U-phase cooling fan UF11 of the eleventh U-phase cooling section UC11 takes in air from the side or the lower side, and supplies cooling air to the eleventh U-phase resistor group UR11 located above.

The eleventh U-phase cooling section UC11 holds the eleventh U-phase resistor group UR11 via an insulator F.

When viewed from the z direction, the eleventh U-phase resistor group UR11 is located on the inner side of the outer shape of the eleventh U-phase cooling section UC11.

### (Attachment of Insulator F)

The lower portion of the insulator F is attached to the frame of the eleventh U-phase cooling section UC11, which is the base portion of the eleventh U-phase cooling section UC11 holding the eleventh U-phase cooling fan UF11, via a first attachment fitting F1 such as channel steel extending in the x direction.

The first attachment fitting F1 is attached to the frame of the eleventh U-phase cooling section UC11, which is the base portion of the eleventh U-phase cooling section UC11 holding the eleventh U-phase cooling fan UF11.

Here, the lower portion of the insulator F may be attached directly to the frame of the eleventh U-phase cooling section UC11, without intervention of the first attachment fitting F1.

The upper portion of the insulator F is attached to a holding frame UR11a that holds the resistors R of the eleventh U-phase resistor group UR11 via a second attachment fitting F2 such as angle steel extending in the x direction.

The second attachment fitting F2 is attached to the holding frame UR11a that holds the resistors R of the eleventh U-phase resistor group UR11.

Here, the upper portion of the insulator F may be attached directly to the holding frame UR11a, without intervention of the second attachment fitting F2.

### (Effects of Attaching Insulator to Holding Frame or Like Via Attachment Fitting)

It is possible to fix an insulator between a cooling section and a holding frame in a simple and reliable manner. Also, it is possible to easily replace only the insulator with a new insulator, compared with a mode in which the insulator is attached directly to a holding frame or the like without any attachment fitting.

### (Hood)

It is desirable that a hood having a substantially hollow rectangular parallelepiped shape surrounding the flow path of the cooling air, formed with a first insulating plate IB1 perpendicular to the x direction and a second insulating plate IB2 perpendicular to the y direction, is provided between the eleventh U-phase cooling section UC11 and the eleventh U-phase resistor group UR11.

The first insulating plate IB1 is attached to a third attachment fitting F3 extending in the y direction by screwing or the like.

The third attachment fitting F3 is attached to the frame of the eleventh U-phase cooling section UC11, which is the base portion of the eleventh U-phase cooling section UC11 holding the eleventh U-phase cooling fan UF11.

The second insulating plate IB2 is attached to the first attachment fitting F1 by screwing or the like.

The members (the first insulating plate IB1 and the second insulating plate IB2) constituting said hood may be formed integrally, or may be formed separately from each other.

Edge portions (upper end portions) of the members (the first insulating plate IB1 and the second insulating plate IB2) constituting said hood are located on the inner side of the holding frame UR11a of the eleventh U-phase resistor group UR11, and are not in contact with said holding frame UR11a.

### (Effects of Providing Hood and Like)

Cooling air from the cooling section can be supplied to the inside of the holding frame without leaking to the outside, while insulation properties are maintained.

The members (the first insulating plate IB1 and the second insulating plate IB2) constituting the hood can be easily attached and detached via the members (the first attachment fitting F1 and the third attachment fitting F3) for securing the insulator F.

Note that, in FIG. 3, the insulator F, the first attachment fitting F1, and the second insulating plate IB2 on the before side in the y direction are not shown.

Also, in FIG. 4, the first insulating plate IB1 on the before side in the x direction is not shown.

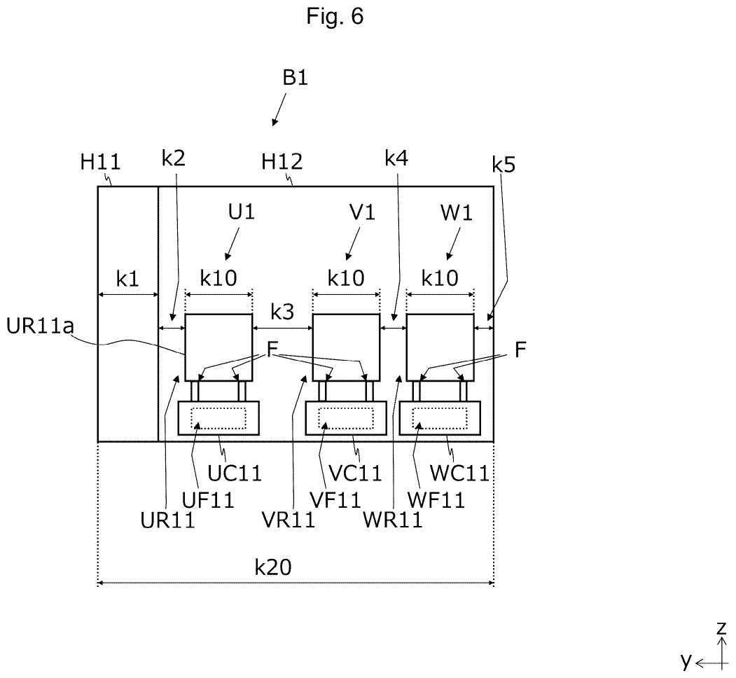

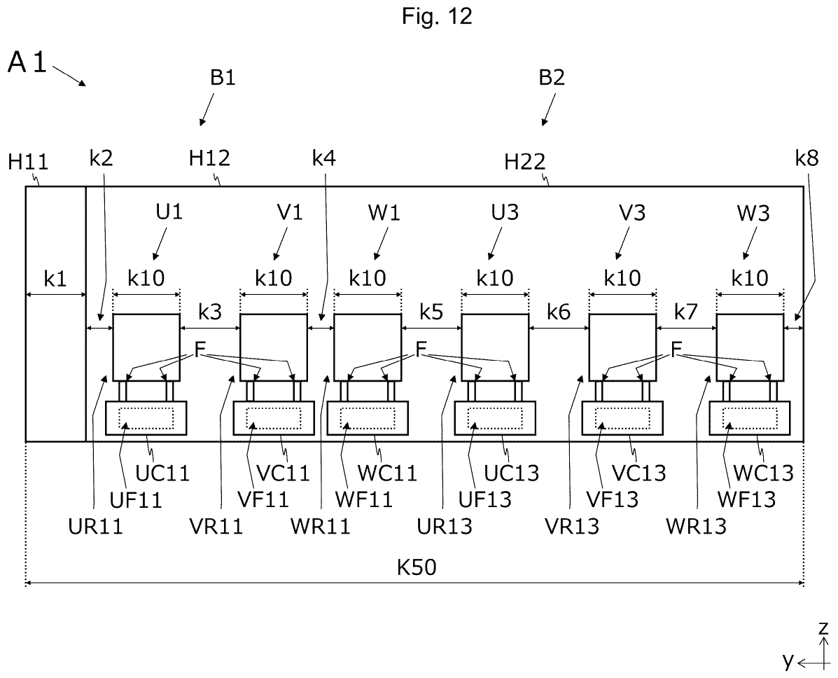

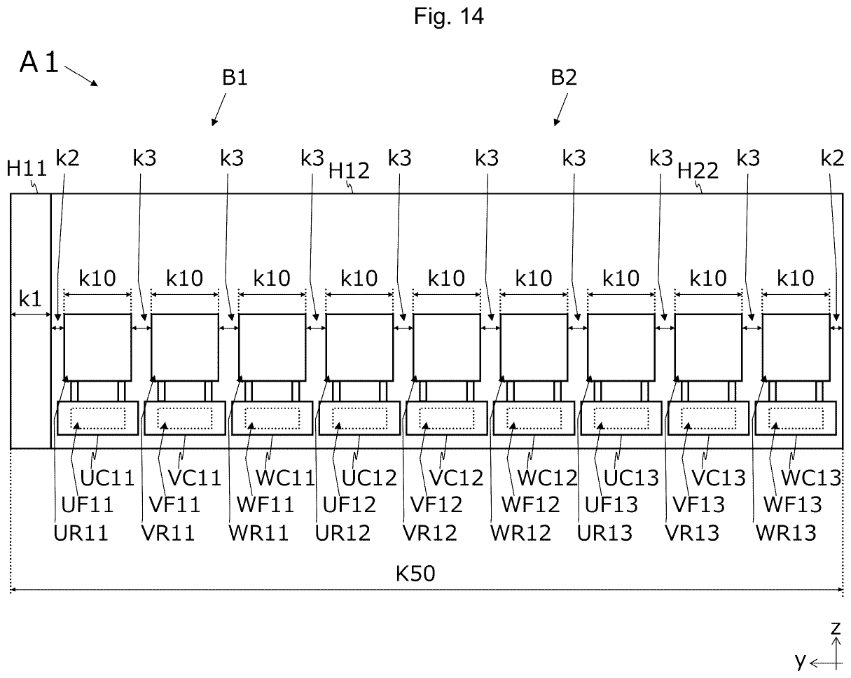

Further, in FIGS. 6, 7, 12, 14, 15, and 17, the first attachment fitting F1, the second attachment fitting F2, the third attachment fitting F3, the first insulating plate IB1, and the second insulating plate IB2 are not shown.

### Application Example 1 of Eleventh U-Phase Cooling Section UC11

As the eleventh U-phase cooling fan UF11, it is desirable to use a cooling fan of a pressurized fan type including a bell mouth UF11c covering the outer periphery of the propeller.

### (Effects of Providing Bell Mouth UF11c)

Even in a mode in which a space for taking in air below the eleventh U-phase cooling fan UF11 is small, it is easy to send cooling air to the eleventh U-phase resistor group UR11 by intake air from the side.

Thus, the dimension in the direction (z direction) in which the eleventh U-phase cooling section UC11 and the eleventh U-phase resistor group UR11 are arranged can be made smaller than that in a mode in which the space for taking in air below the eleventh U-phase cooling fan UF11 is large.

### (Configuration of Eleventh U-Phase Resistor Group UR11)

The eleventh U-phase resistor group UR11 includes a plurality of resistors R.

Each resistor R extends in the y direction, and the plurality of resistors R is arranged in the x direction and the z direction.

The plurality of resistors R is arranged at regular intervals in the x direction (a first direction) and the z direction.

However, in a region (see dotted lines in FIG. 3) including the center in the x direction of a region in which the plurality of resistors R is arranged, or, in other words, in a region including the line along which the rotation axis LX of the eleventh U-phase cooling fan UF11 extends, it is desirable that the resistors R are arranged at wider intervals than in other regions, or, in other words, a non-resistor region NA is formed so that any resistor R is not disposed therein.

### (Effects of Providing Non-Resistor Region NA)

Compared with that in a mode in which the resistors R are arranged at equal intervals in the x direction, the cooling air easily flows in the region including the rotation axis LX.

Also, it is desirable that protrusions UR11b protruding inward are formed on inner walls of the holding frame UR11a that holds the resistors R of the eleventh U-phase resistor group UR11.

### (Effects of Providing Protrusions UR11b on Inner Walls of Holding Frame UR11a)

The protrusions UR11b change the direction in which the cooling air flows, and the cooling air easily diffuses in the holding frame UR11a.

In the first embodiment, an example in which the resistors R extend in the y direction and the plurality of resistors R is arranged in the x direction and the z direction has been described. However, as illustrated in the fourth embodiment described later, the resistors R may extend in the x direction, and the plurality of resistors R may be arranged in the y direction and the z direction. Also, the resistors R may extend in the z direction, and the plurality of resistors R may be arranged in the x direction and the y direction.

Furthermore, the resistors R do not necessarily have a rod-like shape extending in a straight line, and may be formed in some other shape such as a U-shape.

Also, in the first embodiment, an example in which the eleventh U-phase cooling section UC11 and the eleventh U-phase resistor group UR11 are arranged in the z direction has been described. However, the eleventh U-phase cooling section UC11 and the eleventh U-phase resistor group UR11 may be arranged in the x direction or the y direction.

### Application Example 2 of Eleventh U-Phase Cooling Section UC11

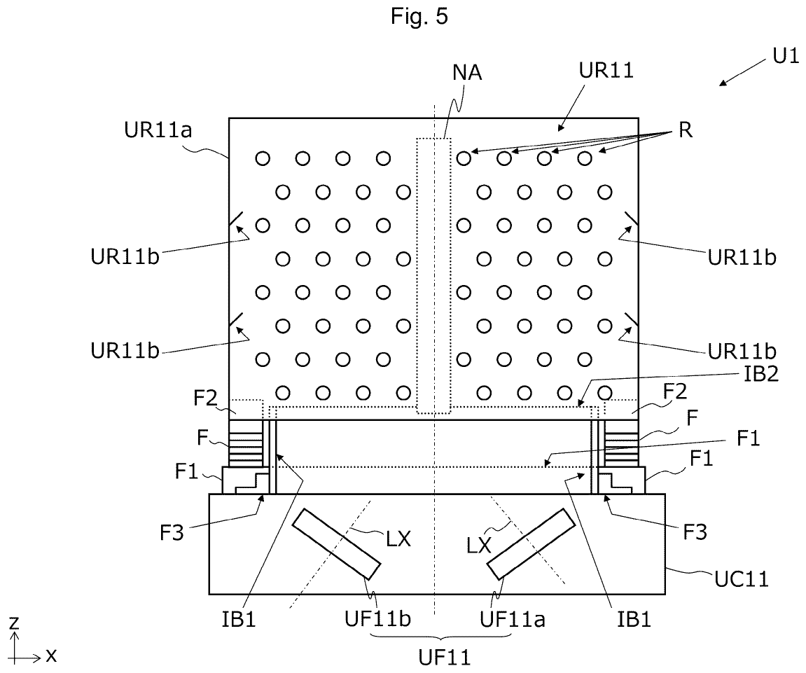

Although the eleventh U-phase cooling fan UF11 may be formed with a single fan, a plurality of fans may be configured to be disposed obliquely (see FIG. 5).

Specifically, the two eleventh U-phase cooling fans UF11a and UF11b are disposed in such a manner that cooling airs are directed obliquely upward, and, when viewed from the z direction, the cooling airs intersect at the center in the x direction and at the center in the y direction of the region including the eleventh U-phase resistor group UR11.

That is, a plurality of cooling fans such as the two eleventh U-phase cooling fans UF11a and UF11b is arranged in an inclined state with respect to the x-y plane perpendicular to the z direction in which the eleventh U-phase cooling section UC11 and the holding frame UR11a of the eleventh U-phase resistor group UR11 are arranged.

### (Effects of Disposing Cooling Fans in Inclined State)

As the cooling airs from the two eleventh U-phase cooling fans UF11a and UF11b collide with each other in the region including the eleventh U-phase resistor group UR11, and the directions in which the cooling airs flow change, the cooling airs easily diffuse in the holding frame UR11a.

Note that the number of the eleventh U-phase cooling fans UF11 disposed obliquely is not limited to two, and may be three or larger.

In this case, the three or more eleventh U-phase cooling fans UF11 or the two eleventh U-phase cooling fans UF11 are directed obliquely upward, and, when viewed from the z direction, the cooling airs intersect at the center in the x direction and at the center in the y direction of the region including the eleventh U-phase resistor group UR11.

However, the fans are not necessarily inclined, and may be disposed in such a manner that the rotation axes LX are parallel to the z direction.

The first V-phase resistance unit V1 and the second V-phase resistance unit V2 each include a plurality of resistor groups and a cooling section that supplies cooling air to said plurality of resistor groups.

The resistor group of the first V-phase resistance unit V1 and the resistor group of the second V-phase resistance unit V2 are connected in series. However, the resistor group of the first V-phase resistance unit V1 and the resistor group of the second V-phase resistance unit V2 may be connected in parallel.

Power from an S-phase terminal of the test target power supply 100 is supplied to the resistor groups of the first V-phase resistance unit V1 and the second V-phase resistance unit V2 via the first breaker section D1 and the first breaker device 15.

Power from an auxiliary power supply provided separately from the test target power supply 100 is supplied to the cooling sections of the first V-phase resistance unit V1 and the second V-phase resistance unit V2.

Here, power from the test target power supply 100 may be supplied to the cooling sections of the first V-phase resistance unit V1 and the second V-phase resistance unit V2.

The first W-phase resistance unit W1 and the second W-phase resistance unit W2 each include a plurality of resistor groups and a cooling section that supplies cooling air to said plurality of resistor groups.

The resistor group of the first W-phase resistance unit W1 and the resistor group of the second W-phase resistance unit W2 are connected in series. However, the resistor group of the first W-phase resistance unit W1 and the resistor group of the second W-phase resistance unit W2 may be connected in parallel.

Power from a T-phase terminal of the test target power supply 100 is supplied to the resistor groups of the first W-phase resistance unit W1 and the second W-phase resistance unit W2 via the first breaker section D1 and the first breaker device 15.

Power from an auxiliary power supply provided separately from the test target power supply 100 is supplied to the cooling sections of the first W-phase resistance unit W1 and the second W-phase resistance unit W2.

Here, power from the test target power supply 100 may be supplied to the cooling sections of the first W-phase resistance unit W1 and the second W-phase resistance unit W2.

The first U-phase resistance unit U1, the first V-phase resistance unit V1, and the first W-phase resistance unit W1 are arranged in the y direction (see FIG. 6).

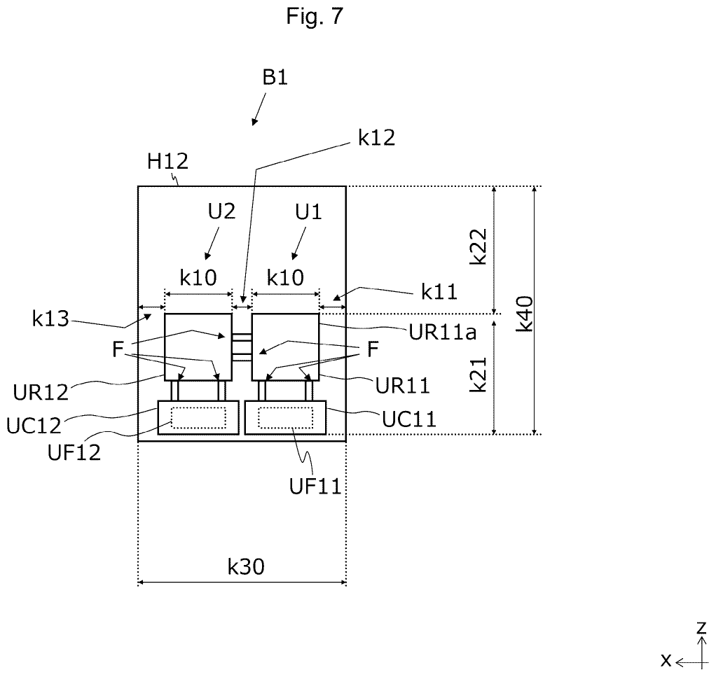

The first U-phase resistance unit U1 and the second U-phase resistance unit U2 are arranged in the x direction, and the insulator F is provided therebetween (see FIG. 7).

The first V-phase resistance unit V1 and the second V-phase resistance unit V2 are arranged in the x direction, and an insulator is provided therebetween.

The first W-phase resistance unit W1 and the second W-phase resistance unit W2 are arranged in the x direction, and an insulator is provided therebetween.

The length of an eleventh housing H11 in the y direction is defined as a first length k1, the distance in the y direction between the holding frame UR11a of the eleventh U-phase resistor group UR11 and a twelfth housing H12 is defined as a second length k2, the distance in the y direction between the holding frame UR11a of the eleventh U-phase resistor group UR11 and the holding frame of the eleventh V-phase resistor group VR11 is defined as a third length k3, the distance in the y direction between the holding frame of the eleventh V-phase resistor group VR11 and the holding frame of the eleventh W-phase resistor group WR11 is defined as a fourth length k4, the distance in the y direction between the holding frame of the eleventh W-phase resistor group WR11 and the twelfth housing H12 is defined as a fifth length k5, and each of the dimension of the holding frame UR11a of the eleventh U-phase resistor group UR11, the holding frame of the eleventh V-phase resistor group VR11, and the holding frame of the eleventh W-phase resistor group WR11 in the x direction and the y direction is defined as a tenth length k10.

Also, the distance in the x direction between the holding frame UR11a of eleventh U-phase resistor group UR11 and the twelfth housing H12 is defined as an eleventh length k11, the distance in the x direction between the holding frame UR11a of the eleventh U-phase resistor group UR11 and the holding frame of the twelfth U-phase resistor group UR12 is defined as a twelfth length k12, and the distance in the x direction between the holding frame of the twelfth U-phase resistor group UR12 and the twelfth housing H12 is defined as a thirteenth length k13.

Further, the dimension in the z direction of the first U-phase resistance unit U1 (the total height of the first U-phase cooling section UC11, the first attachment fitting F1, the insulator F, and the holding frame of the eleventh U-phase resistor group UR11) is defined as a twenty-first length k21, and the distance in the z direction between the upper surface of the holding frame UR11a of the eleventh U-phase resistor group UR11 and the upper surface of the twelfth housing H12 is defined as a twenty-second length k22.

For example, where the first length k1 is 860 mm, the second length k2 is 400 mm, the third length k3 is 900 mm, the fourth length k4 is 400 mm, the fifth length k5 is 200 mm, and the tenth length k10 is 1050 mm, the sum (a twentieth length k20) of the dimension of the eleventh housing H11 in the y direction and the dimension of the twelfth housing H12 in the y direction is about 6000 mm.

Where the eleventh length k11 is 50 mm, the twelfth length k12 is 200 mm, the thirteenth length k13 is 50 mm, and the tenth length k10 is 1050 mm, the dimension (a thirtieth length k30) of the twelfth housing H12 in the x direction is about 2400 mm.

Where the twenty-first length k21 is 2000 mm, and the twenty-second length k22 is 500 mm, the dimension (a fortieth length k40) of the twelfth housing H12 in the z direction is about 2500 mm.

### (Effects of Varying Intervals Between Holding Frames of Resistor Groups)

It is possible to use a 20-feet container as the eleventh housing H11 and the twelfth housing H12, or, in other words, it is possible to house the first load testing section B1 in a 20-foot container, while maintaining sufficient electrical separation between each of the resistor groups and between the resistor group and the housings.

Also, an operator can enter a region having a large interval in the y direction, such as between the first U-phase resistance unit U1 and the first V-phase resistance unit V1, and perform operations such as maintenance.

### (First Control Device 11)

The first control device 11 includes a switching device 11a, and performs on-off control on the power supply from the test target power supply 100 to the six resistance units of the first load testing section B1.

The switching device 11a of the first control device 11 performs on-off control on the power supply to each of the six resistance units of the first load testing section B1, or on-off control on the power supply to each of the resistor groups provided in each of the six resistance units of the first load testing section B1.

Power from an auxiliary power supply provided separately from the test target power supply 100 is supplied to the first control device 11.

Here, power from the test target power supply 100 may be supplied to the first control device 11.

### (First Breaker Device 15)

The first breaker device 15 includes a VCB, is connected to the first breaker section D1 on the input side, and is connected to the first U-phase resistance unit U1, the first V-phase resistance unit V1, and the first W-phase resistance unit W1 on the output side.

The first breaker device 15 performs on-off control on the power supply to at least the resistance units (the first U-phase resistance unit U1, the first V-phase resistance unit V1, and the first W-phase resistance unit W1) connected to the first breaker device 15.

### (Second Load Testing Section B2)

The second load testing section B2 includes six resistance units (a third U-phase resistance unit U3, a fourth U-phase resistance unit U4, a third V-phase resistance unit V3, a fourth V-phase resistance unit V4, the third W-phase resistance unit W3, and a fourth W-phase resistance unit W4), a controller (the second control device 12), and a breaker device (the second breaker device 16).

The third U-phase resistance unit U3 and the fourth U-phase resistance unit U4 each include a plurality of resistor groups and a cooling section that supplies cooling air to said plurality of resistor groups.

The resistor group of the third U-phase resistance unit U3 and the resistor group of the fourth U-phase resistance unit U4 are connected in series. However, the resistor group of the third U-phase resistance unit U3 and the resistor group of the fourth U-phase resistance unit U4 may be connected in parallel.

Power from the R-phase terminal of the test target power supply 100 is supplied to the resistor groups of the third U-phase resistance unit U3 and the fourth U-phase resistance unit U4 via the first breaker section D1 and the second breaker device 16.

Power from an auxiliary power supply provided separately from the test target power supply 100 is supplied to the cooling sections of the third U-phase resistance unit U3 and the fourth U-phase resistance unit U4.

Here, power from the test target power supply 100 may be supplied to the cooling sections of the third U-phase resistance unit U3 and the fourth U-phase resistance unit U4.

Note that, in the third embodiment described later, it is assumed that the resistor group of the third U-phase resistance unit U3 is a thirteenth U-phase resistor group UR13, the cooling section of the third U-phase resistance unit U3 is a thirteenth U-phase cooling section UC13, and the cooling fan of the thirteenth U-phase cooling section UC13 is a thirteenth U-phase cooling fan UF13.

The third V-phase resistance unit V3 and the fourth V-phase resistance unit V4 each include a plurality of resistor groups and a cooling section that supplies cooling air to said plurality of resistor groups.

The resistor group of the third V-phase resistance unit V3 and the resistor group of the fourth V-phase resistance unit V4 are connected in series. However, the resistor group of the third V-phase resistance unit V3 and the resistor group of the fourth V-phase resistance unit V4 may be connected in parallel.

Power from the S-phase terminal of the test target power supply 100 is supplied to the resistor groups of the third V-phase resistance unit V3 and the fourth V-phase resistance unit V4 via the first breaker section D1 and the second breaker device 16.

Power from an auxiliary power supply provided separately from the test target power supply 100 is supplied to the cooling sections of the third V-phase resistance unit V3 and the fourth V-phase resistance unit V4.

Here, power from the test target power supply 100 may be supplied to the cooling sections of the third V-phase resistance unit V3 and the fourth V-phase resistance unit V4.

Note that, in the third embodiment described later, it is assumed that the resistor group of the third V-phase resistance unit V3 is a thirteenth V-phase resistor group VR13, the cooling section of the third V-phase resistance unit V3 is a thirteenth V-phase cooling section VC13, and the cooling fan of the thirteenth V-phase cooling section VC13 is a thirteenth V-phase cooling fan VF13.

The third W-phase resistance unit W3 and the fourth W-phase resistance unit W4 each include a plurality of resistor groups and a cooling section that supplies cooling air to said plurality of resistor groups.

The resistor group of the third W-phase resistance unit W3 and the resistor group of the fourth W-phase resistance unit W4 are connected in series. However, the resistor group of the third W-phase resistance unit W3 and the resistor group of the fourth W-phase resistance unit W4 may be connected in parallel.

Power from the T-phase terminal of the test target power supply 100 is supplied to the resistor groups of the third W-phase resistance unit W3 and the fourth W-phase resistance unit W4 via the first breaker section D1 and the second breaker device 16.

Power from an auxiliary power supply provided separately from the test target power supply 100 is supplied to the cooling sections of the third W-phase resistance unit W3 and the fourth W-phase resistance unit W4.

Here, power from the test target power supply 100 may be supplied to the cooling sections of the third W-phase resistance unit W3 and the fourth W-phase resistance unit W4.

Note that, in the third embodiment described later, it is assumed that the resistor group of the third W-phase resistance unit W3 is a thirteenth W-phase resistor group WR13, the cooling section of the third W-phase resistance unit W3 is a thirteenth W-phase cooling section WC13, and the cooling fan of the thirteenth W-phase cooling section WC13 is a thirteenth W-phase cooling fan WF13.

The third U-phase resistance unit U3, the third V-phase resistance unit V3, and the third W-phase resistance unit W3 are arranged in the y direction.

The third U-phase resistance unit U3 and the fourth U-phase resistance unit U4 are arranged in the x direction, and an insulator is provided therebetween.

The third V-phase resistance unit V3 and the fourth V-phase resistance unit V4 are arranged in the x direction, and an insulator is provided therebetween.

The third W-phase resistance unit W3 and the fourth W-phase resistance unit W4 are arranged in the x direction, and an insulator is provided therebetween.

### (Second Control Device 12)

The second control device 12 includes a switching device 12a, and performs on-off control on the power supply from the test target power supply 100 to the six resistance units of the second load testing section B2.

The switching device 12a of the second control device 12 performs on-off control on the power supply to each of the six resistance units of the second load testing section B2, or on-off control on the power supply to each of the resistor groups provided in each of the six resistance units of the second load testing section B2.

Power from an auxiliary power supply provided separately from the test target power supply 100 is supplied to the second control device 12.

Here, power from the test target power supply 100 may be supplied to the second control device 12.

### (Second Breaker Device 16)

The second breaker device 16 includes a VCB, is connected to the first breaker section D1 on the input side, and is connected to the third U-phase resistance unit U3, the third V-phase resistance unit V3, and the third W-phase resistance unit W3 on the output side.

The second breaker device 16 performs on-off control on the power supply to at least the resistance units (the third U-phase resistance unit U3, the third V-phase resistance unit V3, and the third W-phase resistance unit W3) connected to the second breaker device 16.

(Positional Relationship among Respective Components)

The first load testing section B1 has the eleventh housing H11 and the twelfth housing H12.

The eleventh housing H11 includes the first control device 11 and the first breaker device 15.

The twelfth housing H12 includes the first U-phase resistance unit U1, the second U-phase resistance unit U2, the first V-phase resistance unit V1, the second V-phase resistance unit V2, the first W-phase resistance unit W1, and the second W-phase resistance unit W2.

Here, the switching device 11a of the first control device 11 may be included in the twelfth housing H12.

The surface of the twelfth housing H12 facing a twenty-second housing H22 and the surface of the twenty-second housing H22 facing the twelfth housing H12 may be open.

The second load testing section B2 has a twenty-first housing H21 and the twenty-second housing H22.

The twenty-first housing H21 includes the second control device 12 and the second breaker device 16.

The twenty-second housing H22 includes the third U-phase resistance unit U3, the fourth U-phase resistance unit U4, the third V-phase resistance unit V3, the fourth V-phase resistance unit V4, the third W-phase resistance unit W3, and the fourth W-phase resistance unit W4.

Here, the switching device 12a of the second control device 12 may be included in the twenty-second housing H22.

The respective components are disposed in a positional relationship in which the region (the eleventh housing H11) including the first breaker device 15 and the region (the twenty-second housing H22) including the resistance units of the second load testing section B2 sandwich the region (the twelfth housing H12) including the six resistance units of the first load testing section B1.

The respective components are disposed in a positional relationship in which the region (the twelfth housing H12) including the resistance units of the first load testing section B1 and the region (the twenty-first housing H21) including the second breaker device 16 sandwich the region (the twenty-second housing H22) including the six resistance units of the second load testing section B2.

Note that the eleventh housing H11 may include the second control device 12 and the second breaker device 16.

In this case, the respective components are disposed in a positional relationship in which the region (the eleventh housing H11) including the first breaker device 15 and the second breaker device 16, and the region (the twenty-second housing H22) including the resistance units of the second load testing section B2 sandwich the region (the twelfth housing H12) including the six resistance units of the first load testing section B1.

### (Power Storage Section BT)

In a case where the eleventh U-phase cooling fan UF11 of the eleventh U-phase cooling section UC11 is driven by the power from the test target power supply 100 without any other auxiliary power supply, a power storage section BT is preferably provided in the first load testing device A1.

The power storage section BT stores the power from the test target power supply 100, and, when the power supply from the test target power supply 100 is cut off, drives a cooling fan (such as the eleventh U-phase cooling fan UF11) of the first load testing device A1.

In the first embodiment, an example in which the power storage section BT is provided in the first breaker device 15 and the second breaker device 16 is described.

It is possible to drive each component of the load testing device, using the power from the test target power supply 100, without any auxiliary power supply provided separately from the test target power supply 100.

In particular, since the power storage section stores the power from the test target power supply 100, the cooling fans and the like can be stably driven even when the power supply from the test target power supply 100 is cut off because of on-off control or the like of the test target power supply 100 during a load test.

### (Third Load Testing Section B3 and Others)

The configurations of the third load testing section B3, the fifth load testing section B5, the seventh load testing section B7, the ninth load testing section B9, the eleventh load testing section B11, the thirteenth load testing section B13, the fifteenth load testing section B15, the seventeenth load testing section B17, the nineteenth load testing section B19, the twenty-first load testing section B21, and the twenty-third load testing section B23 are the same as the configuration of the first load testing section B1.

Here, the first breaker devices of the seventh load testing section B7, the ninth load testing section B9, and the eleventh load testing section B11 are connected to the second breaker section D2.

Also, the first breaker devices of the thirteenth load testing section B13, the fifteenth load testing section B15, and the seventeenth load testing section B17 are connected to the third breaker section D3.

Likewise, the first breaker devices of the nineteenth load testing section B19, the twenty-first load testing section B21, and the twenty-third load testing section B23 are connected to the fourth breaker section D4.

### (Fourth Load Testing Section B4 and Others)

The configurations of the fourth load testing section B4, the sixth load testing section B6, the eighth load testing section B8, the tenth load testing section B10, the twelfth load testing section B12, the fourteenth load testing section B14, the sixteenth load testing section B16, the eighteenth load testing section B18, the twentieth load testing section B20, the twenty-second load testing section B22, and the twenty-fourth load testing section B24 are the same as the configuration of the second load testing section B2.

Here, the second breaker devices of the eighth load testing section B8, the tenth load testing section B10, and the twelfth load testing section B12 are connected to the second breaker section D2.

Also, the second breaker devices of the fourteenth load testing section B14, the sixteenth load testing section B16, and the eighteenth load testing section B18 are connected to the third breaker section D3.

Likewise, the second breaker devices of the twentieth load testing section B20, the twenty-second load testing section B22, and the twenty-fourth load testing section B24 are connected to the fourth breaker section D4.

The load testing system 1 according to the first embodiment includes the first load testing device A1 including the first load testing section B1 including the first U-phase resistance unit U1, the second U-phase resistance unit U2, the first V-phase resistance unit V1, the second V-phase resistance unit V2, the first W-phase resistance unit W1, the second W-phase resistance unit W2, and the first breaker device 15, and the second load testing section B2 including the third U-phase resistance unit U3, the fourth U-phase resistance unit U4, the third V-phase resistance unit V3, the fourth V-phase resistance unit V4, the third W-phase resistance unit W3, and the fourth W-phase resistance unit W4, and load testing devices (the second to twelfth load testing devices A2 to A12) equivalent to the first load testing device A1. That is, the load testing system 1 of the first embodiment includes a plurality of sets of load testing devices equivalent to the first load testing device A1.

Among the plurality of load testing devices, power supply from the test target power supply 100 to the first U-phase resistance unit U1, the second U-phase resistance unit U2, the first V-phase resistance unit V1, the second V-phase resistance unit V2, the first W-phase resistance unit W1, and the second W-phase resistance unit W2 is performed via a breaker section (such as the first breaker section D1) provided separately from the first load testing section B1 and via the first breaker device 15.

Also, power supply from the test target power supply 100 to the third U-phase resistance unit U3, the fourth U-phase resistance unit U4, the third V-phase resistance unit V3, the fourth V-phase resistance unit V4, the third W-phase resistance unit W3, and the fourth W-phase resistance unit W4 is performed via a breaker section (such as the first breaker section D1) and via the first breaker device 15 or the second breaker device 16.

### (Effect of Providing Plurality of Resistance Units)

By including large-capacity resistors in the resistor group of each resistance unit, it is possible to safely conduct a load test on the high-voltage test target power supply 100.

In particular, there is no need to step down the voltage of the power from the test target power supply 100 with a transformer or the like.

Thus, unlike a load test involving step-down by a transformer or the like, it is possible to supply power to each load testing section using a thin power supply cable.

Also, unlike a mode involving step-down by a transformer or the like, it is possible to conduct a load test in a state similar to actual use.

Further, the first to twenty-fourth load testing sections B1 to B24 can be used in separate load tests, or can be collectively used in one load test as described above.

### Application of Wiring Lines: Second Embodiment

In the example described in the first embodiment, power from the test target power supply 100 is supplied to the first U-phase resistance unit U1, the first V-phase resistance unit V1, and the first W-phase resistance unit W1 via the first breaker device 15, and power from the test target power supply 100 is supplied to the third U-phase resistance unit U3, the third V-phase resistance unit V3, and the third W-phase resistance unit W3 via the second breaker device 16.

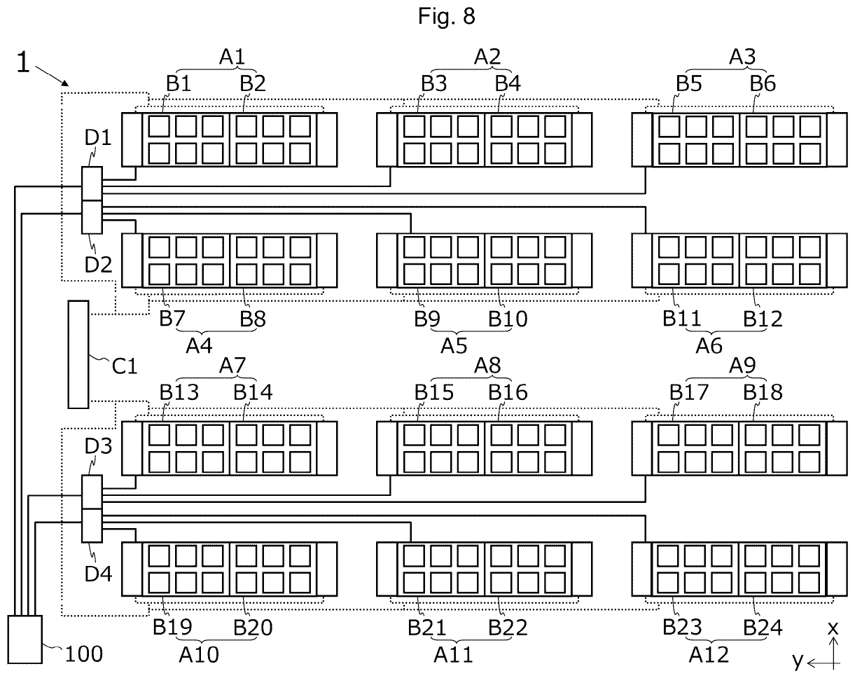

However, power from the test target power supply 100 may be supplied, via the first breaker device 15, to the first U-phase resistance unit U1, the first V-phase resistance unit V1, the first W-phase resistance unit W1, the third U-phase resistance unit U3, the third V-phase resistance unit V3, and the third W-phase resistance unit W3 (second embodiment, see FIGS. 8 and 9).

In this case, the power supply cables from the first breaker device 15 to the third U-phase resistance unit U3, the third V-phase resistance unit V3, and the third W-phase resistance unit W3 can pass through the inside of the twelfth housing H12 and the twenty-second housing H22, and the number of cables visible from the outside can be reduced.

In the second embodiment, the second breaker device 16 may be omitted.

### Application of Wiring Lines: Third Embodiment

In the example described in the second embodiment, the first control device 11 performs on-off control on power supply from the test target power supply 100 to the six resistance units of the first load testing section B1, and the second control device 12 performs on-off control on power supply from the test target power supply 100 to the six resistance units of the second load testing section B2.

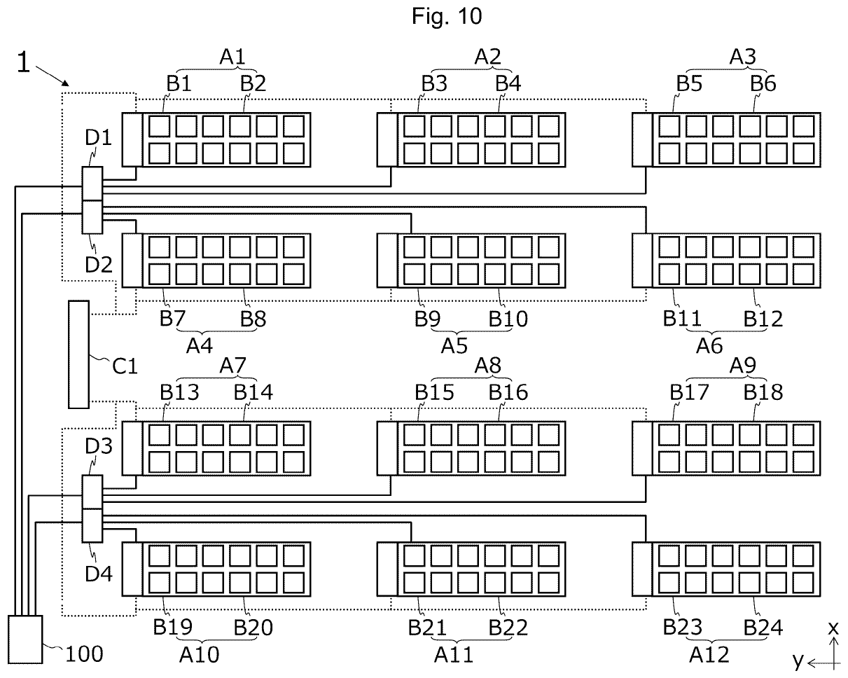

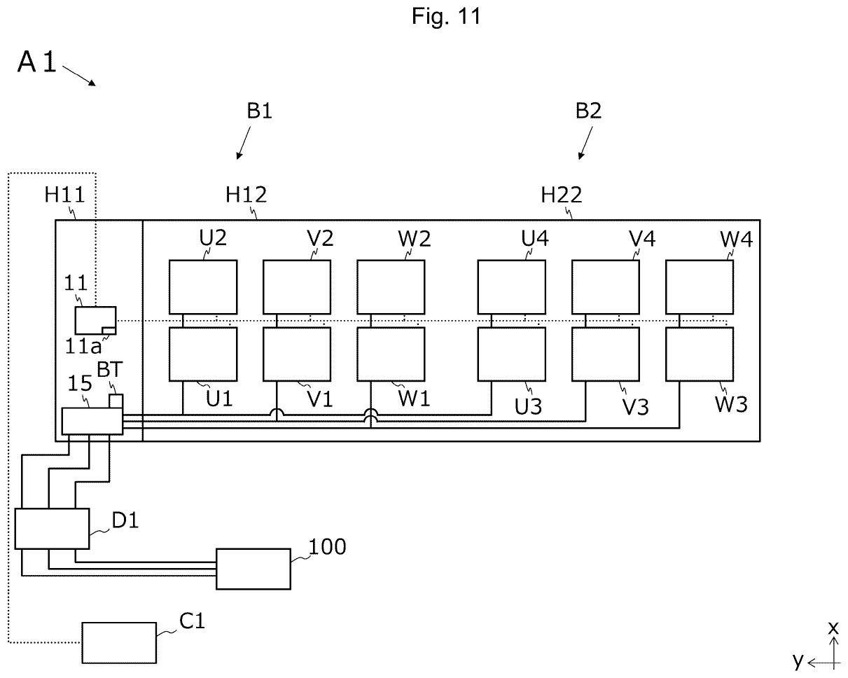

However, the first control device 11 may perform on-off control on power supply from the test target power supply 100 to the six resistance units of the first load testing section B1, and on-off control on power supply from the test target power supply 100 to the six resistance units of the second load testing section B2 (third embodiment, see FIGS. 10 to 12).

In this case, the control signal cables from the controller C1 to the third U-phase resistance unit U3, the fourth U-phase resistance unit U4, the third V-phase resistance unit V3, the fourth V-phase resistance unit V4, the third W-phase resistance unit W3, and the fourth W-phase resistance unit W4 can pass through the inside of the twelfth housing H12 and the twenty-second housing H22, and the number of cables visible from the outside can be reduced.

In the third embodiment, the second control device 12 may be omitted.

Further, the twenty-first housing H21 may also be omitted.

The length of the eleventh housing H11 in the y direction is defined as a first length k1, the distance in the y direction between the holding frame UR11a of the eleventh U-phase resistor group UR11 and the twelfth housing H12 is defined as a second length k2, the distance in the y direction between the holding frame UR11a of the eleventh U-phase resistor group UR11 and the holding frame of the eleventh V-phase resistor group VR11 is defined as a third length k3, the distance in the y direction between the holding frame of the eleventh V-phase resistor group VR11 and the holding frame of the eleventh W-phase resistor group WR11 is defined as a fourth length k4, the distance in the y direction between the holding frame of the eleventh W-phase resistor group WR11 and the holding frame of the thirteenth U-phase resistor group UR13 is defined as a fifth length k5, the distance in the y direction between the holding frame of the thirteenth U-phase resistor group UR13 and the holding frame of the thirteenth V-phase resistor group VR13 is defined as a sixth length k6, the distance in the y direction between the holding frame of the thirteenth V-phase resistor group VR13 and the holding frame of the thirteenth W-phase resistor group WR13 is defined as a seventh length k7, the distance in the y direction between the holding frame of the thirteenth W-phase resistor group WR13 and the twenty-second housing H22 is defined as an eighth length k8, and the dimension of the holding frame UR11a of the eleventh U-phase resistor group UR11, the holding frame of the eleventh V-phase resistor group VR11, the holding frame of the eleventh W-phase resistor group WR11, the holding frame of the thirteenth U-phase resistor group UR13, the holding frame of the thirteenth V-phase resistor group VR13, and the holding frame of the thirteenth W-phase resistor group WR13 in the x direction and the y direction is defined as a tenth length k10.

For example, where the first length k1 is 860 mm, the second length k2 is 400 mm, the third length k3 is 900 mm, the fourth length k4 is 400 mm, the fifth length k5 is 900 mm, the sixth length k6 is 900 mm, the seventh length k7 is 900 mm, the eighth length k8 is 300 mm, and the tenth length k10 is 1050 mm, the sum (a fiftieth length k50) of the dimension of the eleventh housing H11 in the y direction, the dimension of the twelfth housing H12 in the y direction, and the dimension of the twenty-second housing H22 in the y direction is about 12000 mm.

That is, in this example, the region including the first U-phase resistance unit U1, the second U-phase resistance unit U2, the first V-phase resistance unit V1, the second V-phase resistance unit V2, the first W-phase resistance unit W1, and the second W-phase resistance unit W2 is disposed between the region including the first breaker device 15 and the region including the third U-phase resistance unit U3, the fourth U-phase resistance unit U4, the third V-phase resistance unit V3, the fourth V-phase resistance unit V4, the third W-phase resistance unit W3, and the fourth W-phase resistance unit W4, and the distance (the third length k3) in the y direction between the first U-phase resistance unit U1 and the first V-phase resistance unit V1 and the distance (the fifth length k5) in the y direction between the first W-phase resistance unit W1 and the third U-phase resistance unit U3 are larger than the distance (the fourth length k4) in the y direction between the first V-phase resistance unit V1 and the first W-phase resistance unit W1.

In this case, it is possible to use a 40-feet container as the eleventh housing H11, the twelfth housing H12, and the twenty-second housing H22, or, in other words, it is possible to house the first load testing device A1 in a 40-foot container, while maintaining sufficient electrical separation between each of the resistor groups and between the resistor group and the housings.

Also, an operator can enter a region having a large interval in the y direction, such as between the first U-phase resistance unit U1 and the first V-phase resistance unit V1, and perform operations such as maintenance.

### Application of Arrangement of Resistance Units: Fourth Embodiment

In the first to third embodiments, examples in which two resistance units are arranged in the x direction have been described.

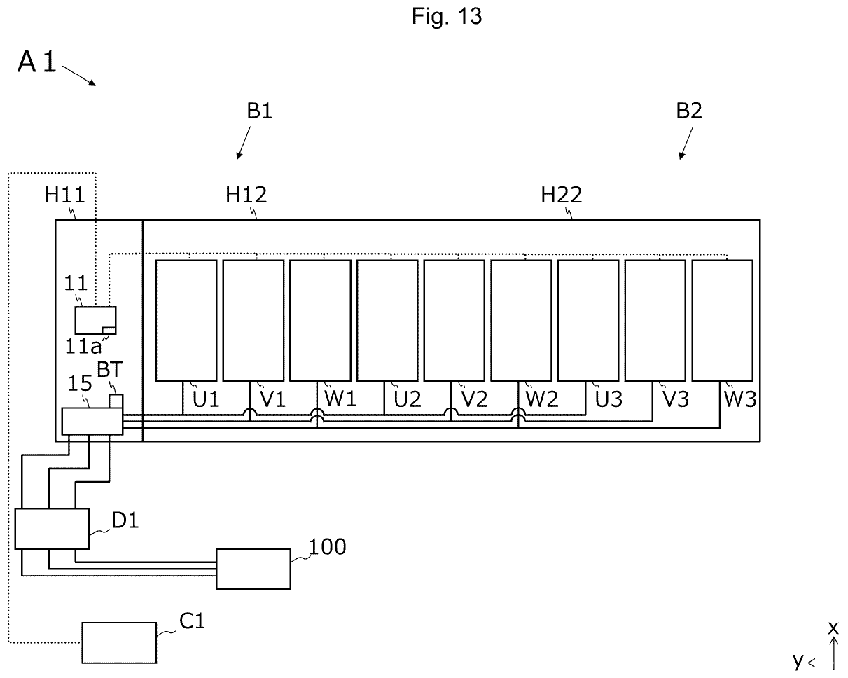

However, only one resistance unit may be disposed in the x direction (fourth embodiment, see FIGS. 13 to 15).

The first load testing section B1 of the fourth embodiment includes the first U-phase resistance unit U1, the second U-phase resistance unit U2, the first V-phase resistance unit V1, the second V-phase resistance unit V2, the first W-phase resistance unit W1, and the second W-phase resistance unit W2.

The second load testing section B2 of the fourth embodiment includes the third U-phase resistance unit U3, the third V-phase resistance unit V3, and the third W-phase resistance unit W3.

In the first load testing device A1 of the fourth embodiment, the first U-phase resistance unit U1, the first V-phase resistance unit V1, the first W-phase resistance unit W1, the second U-phase resistance unit U2, the second V-phase resistance unit V2, the second W-phase resistance unit W2, the third U-phase resistance unit U3, the third V-phase resistance unit V3, and the third W-phase resistance unit W3 are arranged in the y direction.

The resistors R of the resistor group in each resistance unit of the fourth embodiment extend in the x direction.

The surface perpendicular to the x direction of the holding frame of the resistor group in each resistance unit, which is the surface holding terminals of the resistors R is preferably detachable from said holding frame and is preferably covered with a transparent cover UR11c formed with polycarbonate or the like.

In FIG. 15, the transparent covers UR11c provided in the y-z surface of the holding frame UR11a of the eleventh U-phase resistor group UR11 of the first U-phase resistance unit U1, the y-z surface holding the terminals of the resistors R, are indicated by bold lines.

### (Effects of Providing Detachable Transparent Cover UR11c)

Adhesion of dust or the like to the edge portions of the terminals of the resistors R can be reduced.

Furthermore, even in a case where there is adhesion of dust or the like, the dust or the like can be easily recognized with the eye from the outside, and be easily removed.

The resistors R extending in the x direction in the fourth embodiment are longer than the resistors R extending in the y direction in the first to third embodiments.

Two cooling fans are provided in the x direction in the cooling section in each resistance unit.

For example, in the eleventh U-phase cooling section UC11 of the fourth embodiment, two eleventh U-phase cooling fans UF11a and UF11b are arranged side by side in the x direction.

That is, the length of a resistor R extending in the x direction is substantially equal to the length in which the two cooling fans are arranged, as viewed from the z direction. The length (row width) of a resistor group disposed in the y direction is substantially equal to the length (the width of the cooling fan in the y direction) in which one cooling fan is disposed, as viewed from the z direction.

Using resistors R having substantially twice the length of normal resistors R, it is possible to effectively utilize the width of the container in the short-side direction and form a large-capacity resistance unit.

In the eleventh U-phase cooling section UC11, on the upper side of the eleventh U-phase cooling fan UF11a in the z direction and on the side opposite to the side on which the eleventh U-phase cooling fan UF11b is present, a first guide wall UC11a including an inclined surface that guides cooling air from the eleventh U-phase cooling fan UF11a toward the rotation axis LX of the eleventh U-phase cooling fan UF11a is preferably provided.

In the eleventh U-phase cooling section UC11, on the upper side of the eleventh U-phase cooling fan UF11b in the z direction and on the side opposite to the side on which the eleventh U-phase cooling fan UF11a is present, a second guide wall UC11b including an inclined surface that guides cooling air from the eleventh U-phase cooling fan UF11b toward the rotation axis LX of the eleventh U-phase cooling fan UF11b is preferably provided.

### (Effects of Providing Guide Walls)

The direction in which cooling air flows is controlled, and the cooling air is easily supplied to a wide range of the region in which a resistor group including long resistors R is present.

The length of the eleventh housing H11 in the y direction is defined as a first length k1, the distance in the y direction between the holding frame UR11a of the eleventh U-phase resistor group UR11 and the twelfth housing H12 is defined as a second length k2, the distance in the y direction between the holding frame of one of resistor groups adjacent to each other in the y direction and the holding frame of the other one of the adjacent resistor groups is defined as a third length k3, the distance in the y direction between the holding frame of the thirteenth W-phase resistor group WR13 and the twenty-second housing H22 is defined as the second length k2, the dimension of the holding frame of each resistor group in the y direction is defined as a tenth length k10, and the dimension of the holding frame of each resistor group in the x direction is defined as a fifteenth length k15.

Further, the distance in the x direction between the holding frame UR11a of the eleventh U-phase resistor group UR11 and the twelfth housing H12 is defined as an eleventh length k11.

For example, where the first length k1 is 1117 mm, the second length k2 is 150 mm, the third length k3 is 150 mm, and the tenth length k10 is 1050 mm, the sum (a fiftieth length k50) of the dimension of the eleventh housing H11 in the y direction, the dimension of the twelfth housing H12 in the y direction, and the dimension of the twenty-second housing H22 in the y direction is about 12000 mm.

Where the eleventh length k11 is 350 mm, and the fifteenth length k15 is 1700 mm, the dimension (a thirtieth length k30) of the twelfth housing H12 in the x direction is about 2400 mm.

In this case, it is possible to use a 40-feet container as the eleventh housing H11, the twelfth housing H12, and the twenty-second housing H22, while maintaining sufficient electrical separation between each of the resistor groups and between the resistor group and the housings.

Since the resistors R extend in the x direction, it is less necessary for an operator to enter between the adjacent resistor groups, and the width of the adjacent resistor groups in the y direction is set to be narrow.

### (Application of Number of Resistance Units)

In the fourth embodiment, an example in which three U-phase resistance units, three V-phase resistance units, and three W-phase resistance units are provided in one load testing device has been described.

However, the number of resistance units provided in one load testing device is not limited to this.

For example, one U-phase resistance unit, one V-phase resistance unit, and one W-phase resistance unit may be provided as the first load testing section B1, and one U-phase resistance unit, one V-phase resistance unit, and one W-phase resistance unit may be provided as the second load testing section B2.

Alternatively, the second load testing section B2 may be omitted.

Also, an example in which a U-phase resistance unit, a V-phase resistance unit, and a W-phase resistance unit are formed separately from one another has been described.

That is, an example in which the holding frame of a U-phase resistor group, the holding frame of a V-phase resistor group, and the holding frame of a W-phase resistor group are arranged side by side in the x direction or the y direction has been described.

However, the U-phase resistance unit, the V-phase resistance unit, and the W-phase resistance unit may be integrally formed.

Specifically, the resistor groups held in one holding frame includes a resistor group that is used as a U-phase resistor group, a resistor group that is used as a V-phase resistor group, and a resistor group that is used as a W-phase resistor group.

In this case, one cooling section cools the resistor group that is used as a U-phase resistor group, the resistor group that is used as a V-phase resistor group, and the resistor group that is used as a W-phase resistor group among the resistor groups held in said one holding frame.

Therefore, it is also conceivable that only one load testing section is provided in each load testing device, and said one load testing section is formed with one resistance unit (in which a U-phase resistance unit, a V-phase resistance unit, and a W-phase resistance unit are integrally formed).

That is, power supply from the test target power supply 100 to at least one resistance unit in the one or more resistance units is performed via a breaker section (such as the first breaker section D1) provided separately from the load testing device (such as the first load testing device A1), the first breaker device 15, and a switching device (such as the switching device 11a of the first control device 11) of the one or more resistance units.

For example, in the first load testing device A1, the second load testing section B2 is omitted, only the first load testing section B1 is provided, and the one load testing section (the first load testing section B1) is formed with one resistance unit.

In this case, the holding frame may be omitted, and the twelfth housing H12 may be used as a frame for holding a resistor group.

Further, the test target power supply 100 is not necessarily a three-phase AC power generator, and may be a single-phase AC power generator, a DC power generator, or a storage battery.

### Application of Wiring Lines: Fifth Embodiment

In the third embodiment, an example in which the twelfth housing H12 is disposed between the eleventh housing H11 and the twenty-second housing H22 has been described.

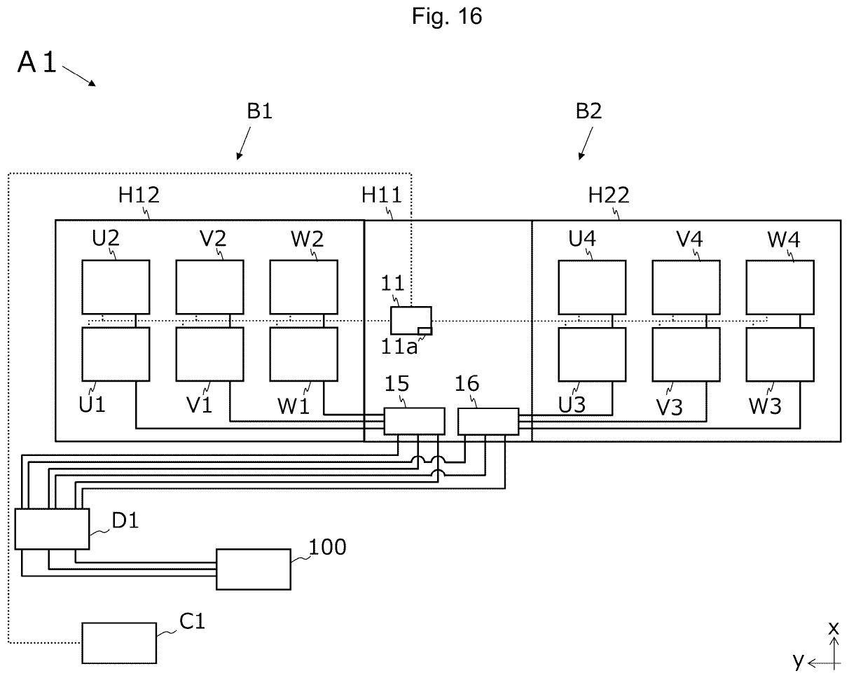

However, the eleventh housing H11 may be disposed between the twelfth housing H12 and the twenty-second housing H22 (fifth embodiment, see FIGS. 16 and 17).

The eleventh housing H11 of the fifth embodiment includes the first control device 11, the first breaker device 15, and the second breaker device 16.

As in the third embodiment, the first control device 11 performs on-off control on power supply from the test target power supply 100 to the six resistance units of the first load testing section B1, and on-off control on power supply from the test target power supply 100 to the six resistance units of the second load testing section B2.

In the fifth embodiment, the second control device 12 is omitted.

Further, the twenty-first housing H21 is also omitted.

Here, the eleventh housing H11 may include the second control device 12, the first control device 11 may perform on-off control on power supply from the test target power supply 100 to the six resistance units of the first load testing section B1, and the second control device 12 may perform on-off control on power supply from the test target power supply 100 to the six resistance units of the second load testing section B2.

As in the first embodiment, power from the test target power supply 100 is supplied to the first U-phase resistance unit U1, the first V-phase resistance unit V1, and the first W-phase resistance unit W1 via the first breaker device 15, and power from the test target power supply 100 is supplied to the third U-phase resistance unit U3, the third V-phase resistance unit V3, and the third W-phase resistance unit W3 via the second breaker device 16.

However, power from the test target power supply 100 may be supplied, via the first breaker device 15, to the first U-phase resistance unit U1, the first V-phase resistance unit V1, the first W-phase resistance unit W1, the third U-phase resistance unit U3, the third V-phase resistance unit V3, and the third W-phase resistance unit W3, as in the third embodiment.

In this case, the second breaker device 16 may be omitted.

The length of the eleventh housing H11 in the y direction is defined as an eleventh length k1, the distance in the y direction between the holding frame UR11a of the eleventh U-phase resistor group UR11 and the twelfth housing H12 is defined as a second length k2, the distance in the y direction between the holding frame UR11a of the eleventh U-phase resistor group UR11 and the holding frame of the eleventh V-phase resistor group VR11 is defined as a third length k3, the distance in the y direction between the holding frame of the eleventh V-phase resistor group VR11 and the holding frame of the eleventh W-phase resistor group WR11 is defined as a fourth length k4, the distance in the y direction between the holding frame of the eleventh W-phase resistor group WR11 and the twelfth housing H12 and the distance in the y direction between the holding frame of the thirteenth U-phase resistor group UR13 and the twenty-second housing H22 are defined as a fifth length k5, the distance in the y direction between the holding frame of the thirteenth U-phase resistor group UR13 and the holding frame of the thirteenth V-phase resistor group VR13 is defined as a sixth length k6, the distance in the y direction between the holding frame of the thirteenth V-phase resistor group VR13 and the holding frame of the thirteenth W-phase resistor group WR13 is defined as a seventh length k7, the distance in the y direction between the holding frame of the thirteenth W-phase resistor group WR13 and the twenty-second housing H22 is defined as an eighth length k8, and the dimension of the holding frame UR11a of the eleventh U-phase resistor group UR11, the holding frame of the eleventh V-phase resistor group VR11, the holding frame of the eleventh W-phase resistor group WR11, the holding frame of the thirteenth U-phase resistor group UR13, the holding frame of the thirteenth V-phase resistor group VR13, and the holding frame of the thirteenth W-phase resistor group WR13 in the x direction and the y direction is defined as a tenth length k10.

For example, where the first length k1 is 1600 mm, the second length k2 is 275 mm, the third length k3 is 820 mm, the fourth length k4 is 820 mm, the fifth length k5 is 225 mm, the sixth length k6 is 820 mm, the seventh length k7 is 820 mm, the eighth length k8 is 275 mm, and the tenth length k10 is 1050 mm, the sum (a fiftieth length k50) of the dimension of the eleventh housing H11 in the y direction, the dimension of the twelfth housing H12 in the y direction, and the dimension of the twenty-second housing H22 in the y direction is about 12000 mm.

In this case, it is possible to use a 40-feet container as the eleventh housing H11, the twelfth housing H12, and the twenty-second housing H22, while maintaining sufficient electrical separation between each of the resistor groups and between the resistor group and the housings.

Furthermore, an operator can enter between the adjacent resistor groups, and perform operations such as maintenance.

In particular, the distance (the third length k3, the fourth length k4, the sixth length k6, the seventh length k7) between adjacent holding frames is preferably set to about 80% of the length (the tenth length k10) of the holding frames.

In this case, the distance between the adjacent holding frames is about 80% of the length in the longitudinal direction of a resistor R substantially equal to the length of the holding frames.

(Effects of Setting Distance Between Holding Frames to about 80% of Length of Holding Frames)

While electrical separation is sufficiently maintained, a container having a predetermined size is used as the eleventh housing H11, the twelfth housing H12, and the twenty-second housing H22, or, in other words, the first load testing device A1 can be housed in a container having a predetermined size, and furthermore, resistors R extending in the y direction can be easily taken out from between a holding frame and a holding frame.

### (Effects of Disposing Eleventh Housing H11 at Center)

The region (the eleventh housing H11) including the first breaker device 15 is disposed at the center in the y direction, and, on both sides of the region, the region (the twelfth housing H12) including the first U-phase resistance unit U1 or the like and the region (the twenty-second housing H22) including the third U-phase resistance unit U3 or the like are disposed, so that the weight balance in the longitudinal direction of one container can be enhanced.

### Application of Wiring Lines: Sixth Embodiment

In the first embodiment, an example in which the load testing system 1 includes twelve load testing devices (the first to twelfth load testing devices A1 to A12) has been described.

However, the number of the load testing devices included in the load testing system 1 is not limited to this.

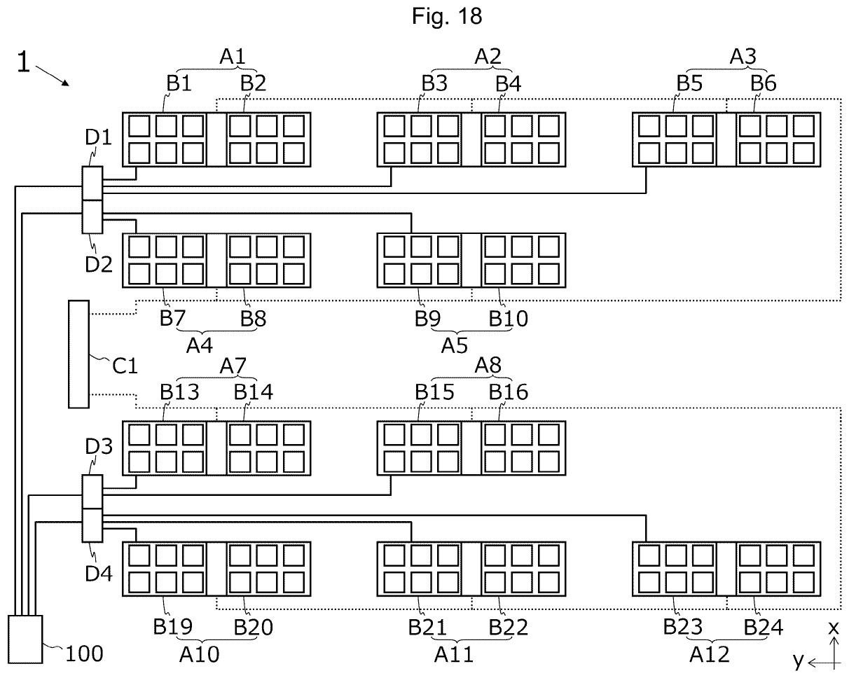

For example, the load testing system 1 may include ten load testing devices (the first to fifth load testing devices A1 to A5, the seventh load testing device A7, the eighth load testing device A8, the tenth to twelfth load testing devices A10 to A12) (sixth embodiment, see FIG. 18).

Although some embodiments of the present invention have been described, these embodiments have been presented as examples, and are not intended to limit the scope of the invention. These embodiments can be implemented in various other forms, and various omissions, substitutions, and changes may be made to them without departing from the gist of the invention. These embodiments and modifications thereof are included in the scope and gist of the invention, and are included in the inventions disclosed in the claims and the equivalent scopes thereof.

### REFERENCE SIGNS LIST

1 Load testing system
11 First control device
11a Switching device of first control device
12 Second control device
12a Switching device of second control device
15 First breaker device
16 Second breaker device
100 Test target power supply
A1 to A12 First load testing device to twelfth load testing device
B1 to B24 First load testing section to twenty-fourth load testing section
BT Power storage section
C1 Controller
D1 to D4 First breaker section to fourth breaker section
F Insulator
F1 First attachment fitting
F2 Second attachment fitting
F3 Third attachment fitting
H11 Eleventh housing
H12 Twelfth housing
H21 Twenty-first housing
H22 Twenty-second housing
IB1 First insulating plate
IB2 Second insulating plate
k1 to k8 First length to eighth length
k10 Tenth length
k11 to k13 Eleventh length to thirteenth length
k15 Fifteenth length
k20 Twentieth length
k21, k22 Twenty-first length, twenty-second length
k30 Thirtieth length
k40 Fortieth length
k50 Fiftieth length
LX Rotation axis of eleventh U-phase cooling fan
NA Non-resistor region
R Resistor
U1 First U-phase resistance unit
U2 Second U-phase resistance unit
U3 Third U-phase resistance unit
U4 Fourth U-phase resistance unit
UC11 Eleventh U-phase cooling section (cooling section of first U-phase resistance unit)
UC11a First guide wall
UC11b Second guide wall
UF11 Eleventh U-phase cooling fan (cooling fan of eleventh U-phase cooling section)
UF11a, UF11b Two eleventh U-phase cooling fans
UF11c Bell mouth
UR11 Eleventh U-phase resistor group (resistor group of first U-phase resistance unit)
UR11a Holding frame of eleventh U-phase resistor group
UR11b Protrusions on holding frame of eleventh U-phase resistor group
UR11c Transparent cover of holding frame of eleventh U-phase resistor group
UC12 Twelfth U-phase cooling section (cooling section of second U-phase resistance unit)
UF12 Twelfth U-phase cooling fan (cooling fan of twelfth U-phase cooling section)
UR12 Twelfth U-phase resistor group (resistor group of second U-phase resistance unit)
UC13 Thirteenth U-phase cooling section (cooling section of third U-phase resistance unit)
UF13 Thirteenth U-phase cooling fan (cooling fan of thirteenth U-phase cooling section)
UR13 Thirteenth U-phase resistor group (resistor group of third U-phase resistance unit)
V1 First V-phase resistance unit
V2 Second V-phase resistance unit
V3 Third V-phase resistance unit
V4 Fourth V-phase resistance unit
VC11 Eleventh V-phase cooling section (cooling section of first V-phase resistance unit)
VF11 Eleventh W-phase cooling fan (cooling fan of eleventh V-phase cooling section)
VR11 Eleventh V-phase resistor group (resistor group of first V-phase resistance unit)
VC13 Thirteenth V-phase cooling section (cooling section of third V-phase resistance unit)
VF13 Thirteenth V-phase cooling fan (cooling fan of thirteenth V-phase cooling section)
VR13 Thirteenth V-phase resistor group (resistor group of third V-phase resistance unit)
W1 First W-phase resistance unit
W2 Second W-phase resistance unit
W3 Third W-phase resistance unit
W4 Fourth W-phase resistance unit
WC11 Eleventh W-phase cooling section (cooling section of first W-phase resistance unit)
WF11 Eleventh V-phase cooling fan (cooling fan of eleventh W-phase cooling section)
WR11 Eleventh W-phase resistor group (resistor group of first W-phase resistance unit)
WC13 Thirteenth W-phase cooling section (cooling section of third W-phase resistance unit)
WF13 Thirteenth W-phase cooling fan (cooling fan of thirteenth W-phase cooling section)
WR13 Thirteenth W-phase resistor group (resistor group of third W-phase resistance unit)

1. A load testing system comprising:
a plurality of sets of load testing devices each including a first load testing section including one or more resistance units and a first breaker device, wherein
power supply from a test target power supply to at least one resistance unit among the one or more resistance units is performed at least via a breaker section separate from the load testing device and the first breaker device,
the breaker section performs on-off control on power supply to at least one load testing device among the plurality of sets of load testing devices, and
the first breaker device performs on-off control on power supply to at least a resistance unit connected to the first breaker device among the one or more resistance units.

2. The load testing system according to claim 1, wherein
the one or more resistance units include a first U-phase resistance unit, a second U-phase resistance unit, a third U-phase resistance unit, a first V-phase resistance unit, a second V-phase resistance unit, a third V-phase resistance unit, a first W-phase resistance unit, a second W-phase resistance unit, and a third W-phase resistance unit,
the load testing device includes: a first load testing section including the first U-phase resistance unit, the second U-phase resistance unit, the first V-phase resistance unit, the second V-phase resistance unit, the first W-phase resistance unit, the second W-phase resistance unit, and the first breaker device; and a second load testing section including the third U-phase resistance unit, the third V-phase resistance unit, and the third W-phase resistance unit,
power supply from the test target power supply to the first U-phase resistance unit, the second U-phase resistance unit, the first V-phase resistance unit, the second V-phase resistance unit, the first W-phase resistance unit, and the second W-phase resistance unit is performed at least via the breaker section and the first breaker device, and
power supply from the test target power supply to the third U-phase resistance unit, the third V-phase resistance unit, and the third W-phase resistance unit is performed at least via the breaker section and the first breaker device or a second breaker device provided in the second load testing section.

3. The load testing system according to claim 2, wherein
resistors of a resistor group of each of the one or more resistance units extend in an x direction,
the first U-phase resistance unit, the second U-phase resistance unit, the third U-phase resistance unit, the first V-phase resistance unit, the second V-phase resistance unit, the third V-phase resistance unit, the first W-phase resistance unit, the second W-phase resistance unit, and the third W-phase resistance unit are arranged in a y direction perpendicular to the x direction, and
of a holding frame holding the resistor group of each of the one or more resistance units, a surface holding terminals of the resistors is covered with a detachable transparent cover.

4. The load testing system according to claim 2, wherein
resistors of a resistor group of each of the one or more resistance units extend in an x direction,
the first U-phase resistance unit, the second U-phase resistance unit, the third U-phase resistance unit, the first V-phase resistance unit, the second V-phase resistance unit, the third V-phase resistance unit, the first W-phase resistance unit, the second W-phase resistance unit, and the third W-phase resistance unit are arranged in a y direction perpendicular to the x direction,
at least the first U-phase resistance unit includes a cooling section that cools the resistor group of the first U-phase resistance unit,
the cooling section of the first U-phase resistance unit includes two cooling fans arranged in the x direction,
a guide wall including an inclined surface is provided in the cooling section of the first U-phase resistance unit, and
the guide wall guides cooling air from one of the cooling fans toward a rotation axis of the one of the cooling fans, and guides cooling air from the other one of the cooling fans toward a rotation axis of the other one of the cooling fans.

5. The load testing system according to claim 2, wherein
the one or more resistance units include the first U-phase resistance unit, the second U-phase resistance unit, the third U-phase resistance unit, a fourth U-phase resistance unit, the first V-phase resistance unit, the second V-phase resistance unit, the third V-phase resistance unit, and a fourth V-phase resistance unit, the first W-phase resistance unit, the second W-phase resistance unit, the third W-phase resistance unit, and a fourth W-phase resistance unit,
the first U-phase resistance unit and the second U-phase resistance unit are arranged in an x direction,
the first V-phase resistance unit and the second V-phase resistance unit are arranged in the x direction,
the first W-phase resistance unit and the second W-phase resistance unit are arranged in the x direction,
the third U-phase resistance unit and the fourth U-phase resistance unit are arranged in the x direction,
the third V-phase resistance unit and the fourth V-phase resistance unit are arranged in the x direction,
the third W-phase resistance unit and the fourth W-phase resistance unit are arranged in the x direction,
the first U-phase resistance unit, the first V-phase resistance unit, the first W-phase resistance unit, the third U-phase resistance unit, the third V-phase resistance unit, and the third W-phase resistance unit are arranged in a y direction perpendicular to the x direction,
the second U-phase resistance unit, the second V-phase resistance unit, the second W-phase resistance unit, the fourth U-phase resistance unit, the fourth V-phase resistance unit, and the fourth W-phase resistance unit are arranged in the y direction,
a region including the first U-phase resistance unit, the second U-phase resistance unit, the first V-phase resistance unit, the second V-phase resistance unit, the first W-phase resistance unit, and the second W-phase resistance unit is disposed between a region including the first breaker device and a region including the third U-phase resistance unit, the fourth U-phase resistance unit, the third V-phase resistance unit, the fourth V-phase resistance unit, the third W-phase resistance unit, and the fourth W-phase resistance unit, and
a distance in the y direction between the first U-phase resistance unit and the first V-phase resistance unit, and a distance in the y direction between the first W-phase resistance unit and the third U-phase resistance unit are longer than a distance in the y direction between the first V-phase resistance unit and the first W-phase resistance unit.

6. The load testing system according to claim 2, wherein
the one or more resistance units include the first U-phase resistance unit, the second U-phase resistance unit, the third U-phase resistance unit, a fourth U-phase resistance unit, the first V-phase resistance unit, the second V-phase resistance unit, the third V-phase resistance unit, and a fourth V-phase resistance unit, the first W-phase resistance unit, the second W-phase resistance unit, the third W-phase resistance unit, and a fourth W-phase resistance unit,
the first U-phase resistance unit and the second U-phase resistance unit are arranged in an x direction,
the first V-phase resistance unit and the second V-phase resistance unit are arranged in the x direction,
the first W-phase resistance unit and the second W-phase resistance unit are arranged in the x direction,
the third U-phase resistance unit and the fourth U-phase resistance unit are arranged in the x direction,
the third V-phase resistance unit and the fourth V-phase resistance unit are arranged in the x direction,
the third W-phase resistance unit and the fourth W-phase resistance unit are arranged in the x direction,
the first U-phase resistance unit, the first V-phase resistance unit, the first W-phase resistance unit, the third U-phase resistance unit, the third V-phase resistance unit, and the third W-phase resistance unit are arranged in a y direction perpendicular to the x direction,
the second U-phase resistance unit, the second V-phase resistance unit, the second W-phase resistance unit, the fourth U-phase resistance unit, the fourth V-phase resistance unit, and the fourth W-phase resistance unit are arranged in the y direction,
the resistors of a resistor group of each of the first U-phase resistance unit, the second U-phase resistance unit, the third U-phase resistance unit, the fourth U-phase resistance unit, the first V-phase resistance unit, the second V-phase resistance unit, the third V-phase resistance unit, the fourth V-phase resistance unit, the first W-phase resistance unit, the second W-phase resistance unit, the third W-phase resistance unit, and the fourth W-phase resistance unit extend in the y direction, and
a distance between a holding frame holding the resistor group in the first U-phase resistance unit and a holding frame holding the resistor group in the first V-phase resistance unit, a distance between the holding frame of the first V-phase resistance unit and a holding frame holding the resistor group in the first W-phase resistance unit, a distance between a holding frame holding the resistor group in the third U-phase resistance unit and a holding frame holding the resistor group in the third V-phase resistance unit, and a distance between the holding frame of the third V-phase resistance unit and a holding frame holding the resistor group in the third W-phase resistance unit are 80% of a width in the y direction of the holding frame of the first U-phase resistance unit.

7. The load testing system according to claim 5, wherein the region including the first breaker device is disposed between the region including the first U-phase resistance unit, the second U-phase resistance unit, the first V-phase resistance unit, the second V-phase resistance unit, the first W-phase resistance unit, and the second W-phase resistance unit, and the region including the third U-phase resistance unit, the fourth U-phase resistance unit, the third V-phase resistance unit, the fourth V-phase resistance unit, the third W-phase resistance unit, and the fourth W-phase resistance unit.

8. The load testing system according to claim 1, wherein
each of the one or more resistance units includes a resistor group, a holding frame that holds the resistor group, and a cooling section that cools the resistor group,
the resistor group includes a plurality of resistors,
the plurality of resistors is arranged in at least a first direction perpendicular to a direction in which the cooling section and the holding frame are arranged, and,
in a region including a line along which a rotation axis of a cooling fan of the cooling section extends and a center in the first direction of a region in which the plurality of resistors is arranged, the resistors are arranged at wider intervals than in other regions in which the plurality of resistors is arranged.

9. The load testing system according to claim 1, wherein
each of the one or more resistance units includes a holding frame that holds a resistor group, and
a protrusion that diffuses cooling air is formed on an inner wall of the holding frame.

10. The load testing system according to claim 1, wherein
each of the one or more resistance units includes a holding frame that holds a resistor group, and a cooling section that cools the resistor group,
the cooling section includes a plurality of cooling fans, and
the plurality of cooling fans is arranged in an inclined state with respect to a plane perpendicular to a direction in which the cooling section and the holding frame are arranged, to make cooling airs collide with each other in a region including the resistor group.

11. The load testing system according to claim 1, further comprising a controller that is connected to each load testing device among the plurality of sets of load testing devices in a wired manner, and transmits a control signal to each load testing device among the plurality of sets of load testing devices.

12. The load testing system according to claim 1, wherein
each of the one or more resistance units includes a cooling section that cools a resistor group,
the cooling section includes a cooling fan that is driven by power from the test target power supply,
the first breaker device has a power storage section that stores power from the test target power supply, and
the power storage section drives the cooling fan when power supply from the test target power supply is cut off.

13. The load testing system according to claim 1, wherein
the plurality of sets of load testing devices includes at least a first load testing device, a second load testing device, a third load testing device, a fourth load testing device, and a fifth load testing device,
the breaker section includes at least a first breaker section and a second breaker section,
power supply from the test target power supply to the first load testing device, the second load testing device, and the third load testing device is performed at least via the first breaker section, and
power supply from the test target power supply to the fourth load testing device and the fifth load testing device is performed at least via the second breaker section.

14. The load testing system according to claim 1, wherein
each of the one or more resistance units includes a resistor group, a holding frame that holds the resistor group, a cooling section that cools the resistor group, and an insulator provided between the holding frame and the cooling section,
the insulator and the cooling section are attached to each other via a first attachment fitting, and
the insulator and the holding frame are attached to each other via a second attachment fitting separate from the first attachment fitting.

15. The load testing system according to claim 14, wherein
each of the one or more resistance units includes a hood including a first insulating plate and a second insulating plate,
the first insulating plate is attached to the cooling section via a third attachment fitting separate from the first attachment fitting and the second attachment fitting,
the second insulating plate is attached to the cooling section via the first attachment fitting, and
an edge portion of the hood is located on an inner side of the holding frame.

16. The load testing system according to claim 14, wherein the cooling section includes a cooling fan of a pressurized fan type including a bell mouth.

17. The load testing system according to claim 1, wherein
power supply from the test target power supply to at least one resistance unit among the one or more resistance units is performed at least via the breaker section, the first breaker device, and a switching device of the one or more resistance units, and
the switching device performs on-off control on power supply to each of the one or more resistance units, or on-off control on power supply to each resistor group among a plurality of resistor groups provided in each of the one or more resistance units.

18. The load testing system according to claim 1, wherein
the one or more resistance units are formed with one resistance unit, and
a housing of each load testing device among the plurality of sets of load testing devices holds a resistor group in the one resistance unit.
